(19) United States
(12) Patent Application Publication
(10) Pub. No.: US 2025/0034706 A1
(43) Pub. Date: Jan. 30, 2025

(54) Two-Axis Printing for More Uniform Films in an Atmospheric-Pressure Spatial Atomic Layer Deposition Process

(71) Applicant: THE REGENTS OF THE UNIVERSITY OF MICHIGAN, ANN ARBOR, MI (US)

(72) Inventors: Neil P. Dasgupta, ANN ARBOR, MI (US); Daniel Penley, ANN ARBOR, MI (US)

(21) Appl. No.: 18/783,878

(22) Filed: Jul. 25, 2024

Related U.S. Application Data
(60) Provisional application No. 63/515,378, filed on Jul. 25, 2023.

(51) Int. Cl. C23C 16/455; C23C 16/40; C23C 16/458; C23C 16/52

(52) U.S. Cl. CPC C23C 16/45544; C23C 16/405; C23C 16/45565; C23C 16/4583; C23C 16/52

(57) ABSTRACT

An atomic layer deposition system comprises: a depositor head having an active surface configured to discharge a first precursor gas, a second precursor gas, and an inert gas that separates the first precursor gas and the second precursor gas; a substrate spaced apart from the active surface of the depositor head; an XY motion device operably coupled to the substrate or the depositor head; and a controller configured to execute a program stored in the controller to move the XY motion device such that the substrate or the depositor head moves in a path, wherein a position of the substrate relative to the depositor head varies in both an X direction and a Y direction when the substrate or the depositor head follows the path. Also disclosed are a method for atomic layer deposition, and a method for reducing non-uniformity of a film produced by atomic layer deposition.

### CROSS-REFERENCES TO RELATED APPLICATIONS

This application is based on, claims benefit of, and claims priority to U.S. Application No. 63/515,378 filed on Jul. 25, 2023, which is hereby incorporated by reference herein in its entirety for all purposes.

### STATEMENT REGARDING FEDERALLY SPONSORED RESEARCH

This invention was made with government support under grant number 1751590 awarded by the National Science Foundation. The government has certain rights in this invention.

### FIELD OF THE INVENTION

This invention relates to atmospheric-pressure spatial atomic layer deposition systems, and more particularly to an atmospheric-pressure spatial atomic layer deposition system that reduces the non-uniformity of the film produced by the atomic layer deposition system.

### BACKGROUND

Atomic layer deposition (ALD) is a thin-film deposition technique that is capable of conformally coating a substrate, typically an ultra-high-aspect ratio substrate, with an angstrom-scale film of an ALD material one atomic layer at a time. ALD involves sequentially exposing a designated portion of a build substrate to first and second ALD precursor gases. Each of the ALD precursor gases includes reactive ligands that participate in a self-limiting surface reaction to chemically deposit an atomic monolayer of the reacted precursor gases. The two atomic monolayers that are derived alternately from the ALD precursor gases together produce a single atomic layer of the ALD material film upon completion of their reaction. As such, the thickness of the ALD material film can be controlled by varying the number of ALD cycles performed and, thus, the number of atomic layers of the ALD material that are chemically deposited in a layer-by-layer fashion. The ALD material film exhibits a linear growth rate; that is, the thickness of the film is proportional to the number of ALD cycles performed. The material that can be deposited by ALD can range from oxides to nitrides, sulfides, carbides, and/or metals by exploiting the self-limiting binary chemical reactions of ALD.

Spatial atomic layer deposition (SALD) is a specific version of ALD where the ALD cycles are spatially controlled by exposing the build substrate to different precursor gas zones rather than a conventional temporally controlled ALD process where long purging of the precursor gases in a static chamber is required. In SALD, the time-consuming purge step of conventional ALD is not practiced, which expediates the process by about three orders of magnitude, without sacrificing the self-limiting, conformal growth of the ALD material film. As a result, the net deposition rate of SALD is much greater compared to conventional ALD, which enables higher throughput in a shorter amount of time.

An SALD apparatus that performs the SALD process includes a depositor head that discharges at least one flow of each of the ALD precursor gases. The flows of the ALD precursor gases are separated by a flow of an inert gas. The gas flows discharged from the depositor head may extend linearly and parallel to one another to establish an elongated zone of each of the ALD precursor gases and an elongated inert gas curtain that isolates the ALD precursor gas zones for at least a certain distance away from the depositor head. In addition to the depositor head, the SALD apparatus also includes a substrate plate that opposes the depositor head and retains the build substrate onto which the ALD material film is grown. SALD can be performed at atmospheric pressure since the reactive ALD precursor gases are confined spatially by the inert gas zones. The substrate plate is oriented spatially with respect to the depositor head to facilitate the SALD process. In particular, the substrate plate and the depositor head are spaced apart by a gap, which is preferably maintained as uniform as possible in an effort to achieve parallelism between the depositor head and the substrate plate. The gap is typically relatively small, on the order of several tens to several hundreds of microns, to ensure isolation of the precursor gas zones. An example spatial atomic layer deposition system can be found in U.S. Patent Application Publication No. 2023/0097272, which is hereby incorporated by reference in its entirety.

Among the state-of-the-art close-proximity atmospheric-pressure spatial atomic layer deposition (AP-SALD) systems, there are a variety of depositor head designs, all of which will have large impacts on the thickness uniformity and overall shape of the deposited film. This variance in deposited film geometries is undesirable when considering large-scale manufacturing as uniform thin films are highly desirable for optical, electrical, and encapsulation applications.

What is needed therefore is an improved atmospheric-pressure spatial atomic layer deposition (AP-SALD) system that reduces the non-uniformity of the film produced by the atomic layer deposition system.

### SUMMARY

We have developed a customized motion atmospheric-pressure spatial atomic layer deposition (AP-SALD) system that enables mechatronic control of key process parameters, notably the axis of motion during film deposition (i.e., printing). A substrate plate is mounted atop two orthogonal linear stages creating the x-axis and y-axis. The linear stages can be driven individually or simultaneously, allowing for a customized path of relative motion between the substrate and the depositor head. This new capability allows one to achieve more uniform film thicknesses and shapes by adjusting the substrate path of motion to account for inconsistencies in the depositor head.

In one aspect, the present disclosure provides an atmospheric-pressure spatial atomic layer deposition system comprising: a depositor head having an active surface configured to discharge a flow of a first precursor gas, a flow of a second precursor gas, and a flow of an inert gas that separates the flow of the first precursor gas and the flow of the second precursor gas; a substrate spaced apart from the active surface of the depositor head; an XY motion device operably coupled to the substrate or the depositor head; and a controller in electrical communication with the XY motion device, the controller being configured to execute a program stored in the controller to move the XY motion device such that the substrate or the depositor head moves in a path, wherein a position of the substrate relative to the depositor head varies in both an X direction and a Y direction when the substrate or the depositor head follows the path.

In another aspect, the present disclosure provides a method for atomic layer deposition. The method comprises: (a) providing an atomic layer deposition system comprising a depositor head and a substrate; (b) supplying a first precursor gas, a second precursor gas, and an inert gas to the depositor head; and (c) moving the substrate or the depositor head in a path selected to produce a film having a uniform thickness on the substrate wherein a position of the substrate relative to the depositor head varies in both an X direction and a Y direction when the substrate or the depositor head follows the path.

In yet another aspect, the present disclosure provides a method for reducing non-uniformity of a film produced by atomic layer deposition. The method comprises: (a) providing an atomic layer deposition system comprising a depositor head and a substrate; (b) supplying a first precursor gas, a second precursor gas, and an inert gas to the depositor head; and (c) moving the substrate or the depositor head in a path selected to produce a film having a uniform thickness on the substrate wherein a position of the substrate relative to the depositor head varies in both an X direction and a Y direction when the substrate or the depositor head follows the path.

The foregoing and other aspects and advantages of the invention will appear from the following description. In the description, reference is made to the accompanying drawings which form a part hereof, and in which there is shown by way of illustration example embodiments of the invention. Such embodiments do not necessarily represent the full scope of the invention, however, and reference is made therefore to the claims and herein for interpreting the scope of the invention.

### BRIEF DESCRIPTION OF DRAWINGS

FIG. 1 shows a schematic in panel a), a conventional atomic layer deposition with a substrate exposed to temporally separated pulses of precursors A and B between purge steps, each with a characteristic time, in panel b), a spatial atomic layer deposition (SALD) with a substrate moving between precursors A and B and inert zones, each with characteristic length, and in panel c), a close-proximity spatial ALD, showing the gas/precursor zones formed in the gap between the depositor and substrate and the relative motion that enables alternating precursor exposures.

FIG. 2 shows in panel a), a perspective view of an atmospheric-pressure spatial atomic layer deposition system according to one example embodiment of the present disclosure. The depositor is fixed to the top plate, which is used to define its orientation using two linear actuators (L4 and L5) and a pivot point (P). The substrate plate is located below the depositor. The motion of the substrate is controlled by two precision motorized stages (X and Y). In panel b), three capacitance probe sensors (C1, C2, and C3) are mounted to the depositor and three linear actuators (L1, L2, and L3) are used to define the orientation of the substrate plate. Note that C1 and L1 are on the backside of the system and are not directly visible. In panel c), a photograph of a prototype system is provided and cross-labeled.

FIG. 3 shows in panel a), a perspective view of the atmospheric-pressure spatial atomic layer deposition system of FIG. 2 showing the process region of gas/precursor zones formed between the depositor and substrate plate. The depositor is mounted to the top plate. The substrate plate and its alignment system are mounted to two motorized stages (X and Y) that control the position and velocity of the substrate plate. Vertical scale bar indicates 100 mm. Panel b) is a bottom view of the depositor showing the pinholes of the showerhead design which form the gas/precursor zones. Center-to-center pinhole spacings are shown. Panel c) shows a cross-section view of the depositor showing the gas zones (metal precursor, water precursor, inner nitrogen, and outer nitrogen) and exhaust lines. The target substrate is moved relative to these zones for alternating precursor exposure.

FIG. 4 is a simplified perspective view of the atmospheric-pressure spatial atomic layer deposition system of FIG. 2 showing the three planes of interest. Plane 1 (P1) is defined as the bottom surface of the depositor, and its rotational orientation can be controlled about the x₁ and y₁ axes. Plane 2 (P2) is defined as the top surface of the substrate plate, and its rotational orientation can be controlled about the x₂ and y₂ axes. Additionally, its translational position can be controlled along the z₂ axis to adjust the gap size (Δz). Plane 3 (P3) is defined as the top surface of the orthogonal motorized stage stack, which can be translated along the x₃ and y₃ axes.

FIG. 5 shows a stationary and path-dependent alignment control. Panel a) is a schematic of initial (stationary) misalignment before SALD deposition. Panel b) is an experimental demonstration of closed-loop control of stationary alignment. Panel c) is a schematic of path-dependent misalignment during SALD deposition, where gap size (Δz₁ and Δz₂) varies as a function of position. Panel d) is an experimental demonstration of the effect of closed-loop path-dependent alignment control on gap size variation during printing motion.

FIG. 6 shows the average gap size as a function of AP-SALD cycles to demonstrate the system drift during a deposition process with and without correction.

FIG. 7 shows in panel a), thickness of deposited TiO₂ films as a function of Spatial ALD cycles. Growth per cycle (GPC) is calculated as 0.54 Å cycle⁻¹ via the linear fit of the data points (dashed line). For each deposition, the substrate velocity was maintained at 20 mm s⁻¹ over a linear travel distance of ±23 mm, resulting in a cycle time of 4.6 seconds. Panel b) shows growth per cycle (GPC) as a function of TTIP bubbler flow rate. Saturated growth rate of 0.51 A cycle⁻¹ is shown with the dashed line. Error bars in both panels represent the standard deviation of 20 independent measurements within the process region. All measurements were taken with ellipsometry.

FIG. 8 shows an XPS survey scan of AP-SALD TiO₂ film with an inset that shows the estimated atomic percentages.

FIG. 9 shows a uniaxial printing motion produces in panel a), a precursor concentration gradient as a result of depositor pinhole design, which creates non-uniformity in the film thickness that can be seen in panel b), optically and in panel c), in a thickness line scan Lu. The effects of multi-axis printing motions can be seen by the panel d) improved uniformity of the precursor gradient, which deposits a more uniform film as seen in panel e), the thickness line scan Lm and in panel f), optically. Note that the thickness line scans were measured over the same spatial coordinates on both samples.

FIG. 10 shows a schematic of full AP-SALD system including the flow control system and temperature zones.

FIG. 11 shows assorted views of the four pieces that comprise the depositor manifold of the atmospheric-pressure spatial atomic layer deposition system of FIG. 2.

FIG. 12 shows schematics and images depicting the effect of x-axis travel on the deposited region geometry and thickness. Three different regions are shown ±20 mm (single layer), ±23 mm (transition region), and ±35 mm (double layer).

FIG. 13 shows optical images of deposited TiO₂ films using uniaxial (left) and multi-axis (right) printing motions.

FIG. 14 shows optical images of deposited TiO₂ films using 10 mm s⁻¹ (left) and 20 mm s⁻¹ (right) for the substrate velocity while printing.

Like reference numerals will be used to refer to like parts from Figure to Figure in the following description of the drawings.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown but are to be accorded the widest scope consistent with the principles and features disclosed herein. Skilled artisans will recognize the examples provided herein have many useful alternatives and fall within the scope of embodiments of the invention.

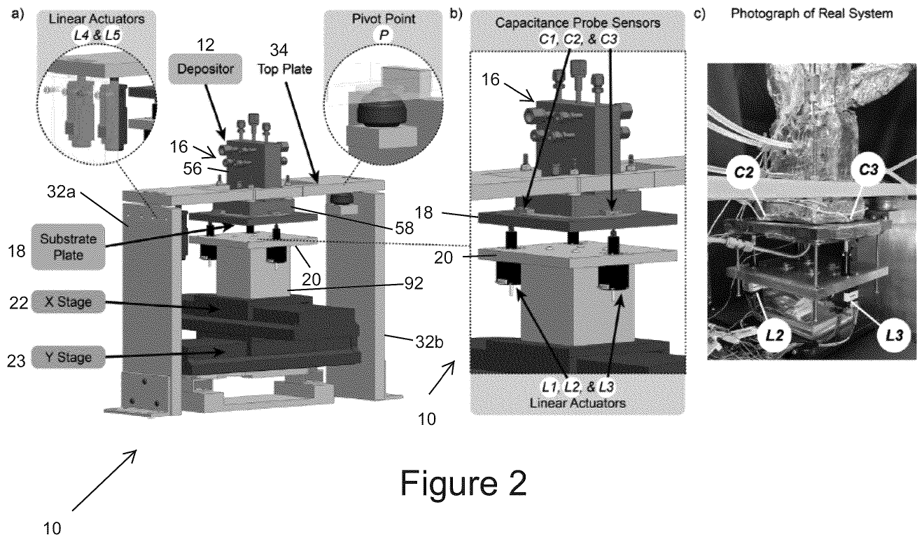

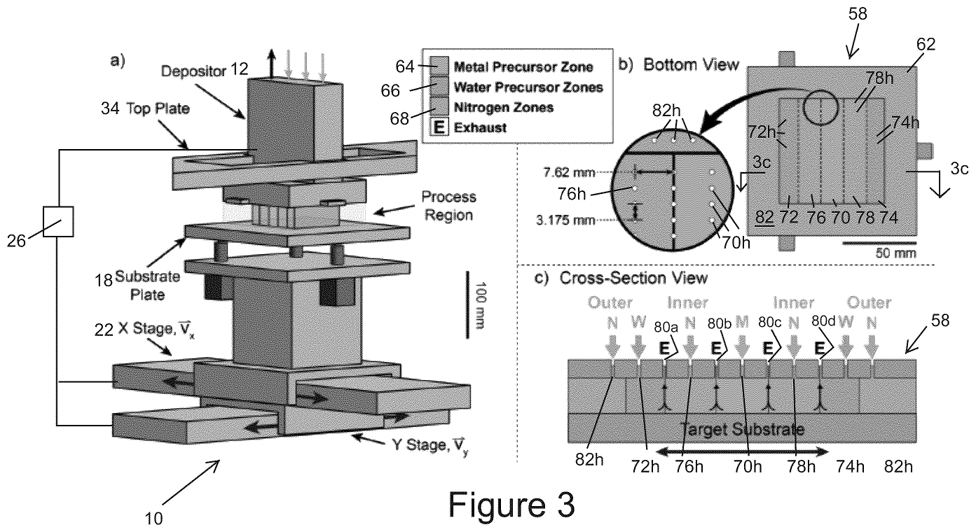

Close-proximity atmospheric-pressure spatial atomic layer deposition (AP-SALD) holds promise to address the large-scale manufacturing needs of interfacial engineering at the nanoscale. In this process, a depositor head creates precursor zones that are separated with inert gas curtains and exhaust lines to isolate the precursors and prevent transport of oxygen from the surroundings. The substrate is brought in close proximity to the depositor head and then moved relative to the zones, exposing the substrate to alternating precursors and depositing a film. A showerhead depositor head design according to the present disclosure (see FIGS. 2 and 3 and the description below) has a process area of approximately 4×4 inches and uses pinholes with positive flows to create the necessary gas curtains and negative flows to exhaust the excess gas and byproducts. Among the state-of-the-art close-proximity AP-SALD systems, there are a variety of depositor head designs, all of which will have large impacts on the thickness uniformity and overall shape of the deposited film. This variance in deposited film geometries is undesirable when considering large-scale manufacturing as uniform thin films are highly desirable for optical, electrical, and encapsulation applications.

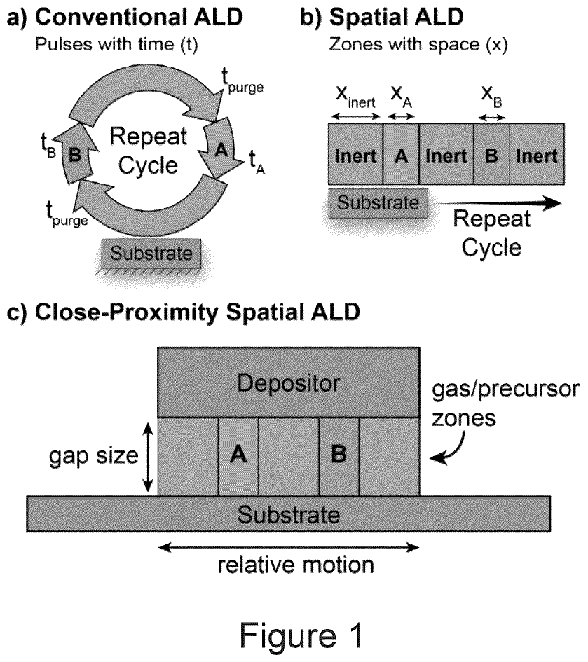

We have developed a customized motion atmospheric-pressure spatial atomic layer deposition (AP-SALD) system that enables mechatronic control of key process parameters, notably the axis of motion during film deposition (i.e., printing). As shown in FIG. 1 and described below, the substrate plate is mounted atop two orthogonal linear stages creating the x-axis and y-axis. The linear stages can be driven individually or simultaneously, allowing for a customized path of relative motion between the substrate and the depositor head. This new capability allows one to achieve more uniform film thicknesses and shapes by adjusting the substrate path of motion to account for inconsistencies in the depositor head.

The present disclosure provides an atomic layer deposition system comprising: a depositor head having an active surface configured to discharge a flow of a first precursor gas, a flow of a second precursor gas, and a flow of an inert gas that separates the flow of the first precursor gas and the flow of the second precursor gas; a substrate spaced apart from the active surface of the depositor head; an XY motion device operably coupled to the substrate or the depositor head; and a controller in electrical communication with the XY motion device, the controller being configured to execute a program stored in the controller to move the XY motion device such that the substrate or the depositor head moves in a path, wherein a position of the substrate relative to the depositor head varies in both an X direction and a Y direction when the substrate or the depositor head follows the path. The path can be selected to produce a film having a uniform thickness over a region of the film on the substrate.

The atomic layer deposition system can further comprise a first precursor gas source for containing the first precursor gas, a second precursor gas source for containing the second precursor gas, and a third source for containing the inert gas, and the active surface of the depositor head includes a plurality of first passageways in fluid communication with the first precursor gas source via a first precursor gas conduit, a plurality of second passageways in fluid communication with the second precursor gas source via a second precursor gas conduit, and a plurality of third passageways in fluid communication with the third source via a gas conduit, and the system can further comprise a valve apparatus comprising: (i) a first valve in the first precursor gas conduit, (ii) a second valve in the second precursor gas conduit, and (iii) a third valve in the gas conduit, and the controller is in electrical communication with the valve apparatus, the controller being configured to execute the program stored in the controller to move the first valve, the second valve, and the third valve into an open position to deliver the first precursor gas to a first reaction zone between the active surface of the depositor head and the substrate, to deliver the second precursor gas to a second reaction zone between the active surface of the depositor head and the substrate, and to deliver the inert gas to a gas barrier zone between the active surface of the depositor head and the substrate.

In one embodiment of the atomic layer deposition system, the first passageways, the second passageways, and the third passageways are arranged in linear rows. In one embodiment of the atomic layer deposition system, the active surface of the depositor head further comprises a plurality of exhaust passageways, each of the plurality of exhaust passageways being in fluid communication with one of a plurality of exhaust zones between the active surface of the depositor head and the substrate. In one embodiment of the atomic layer deposition system, the substrate is positioned on a substrate plate connected to the XY motion device, and the controller executes the program stored in the controller to move the XY motion device such that the substrate plate moves in the path wherein the position of the substrate plate relative to the depositor head varies in both the X direction and the Y direction when the substrate plate follows the path. In one embodiment of the atomic layer deposition system, the XY motion device is connected to the depositor head. In one embodiment of the atomic layer deposition system, the path has a shape selected from the group consisting of closed shapes having a plurality of line segments, open shapes having a plurality of line segments, and wave shaped. In one embodiment of the atomic layer deposition system, the path has a rectangular shape.

The present disclosure also provides a method for atomic layer deposition. The method comprises: (a) providing an atomic layer deposition system comprising a depositor head and a substrate; (b) supplying a first precursor gas, a second precursor gas, and an inert gas to the depositor head; and (c) moving the substrate or the depositor head in a path selected to produce a film having a uniform thickness on the substrate wherein a position of the substrate relative to the depositor head varies in both an X direction and a Y direction when the substrate or the depositor head follows the path. In one embodiment of the method, the atomic layer deposition system comprises an XY motion device operably coupled to the substrate or the depositor head, and the XY motion device moves such that the position of the substrate relative to the depositor head varies in both the X direction and the Y direction when the substrate or the depositor head follows the path. In one embodiment of the method, the atomic layer deposition system comprises an XY motion device operably coupled to the substrate, and the XY motion device moves such that the position of the substrate relative to the depositor head varies in both the X direction and the Y direction when the substrate follows the path. In one embodiment of the method, the substrate is positioned on a substrate plate connected to the XY motion device. In one embodiment of the method, the atomic layer deposition system comprises an XY motion device operably coupled to the depositor head, and the XY motion device moves such that the position of the substrate relative to the depositor head varies in both the X direction and the Y direction when the depositor head follows the path. In one embodiment of the method, the path has a shape selected from the group consisting of closed shapes having a plurality of line segments, open shapes having a plurality of line segments, and wave shaped. In one embodiment of the method, the path has a rectangular shape.

The present disclosure also provides a method for reducing non-uniformity of a film produced by atomic layer deposition. The method comprises: (a) providing an atomic layer deposition system comprising a depositor head and a substrate; (b) supplying a first precursor gas, a second precursor gas, and an inert gas to the depositor head; and (c) moving the substrate or the depositor head in a path selected to produce a film having a uniform thickness on the substrate wherein a position of the substrate relative to the depositor head varies in both an X direction and a Y direction when the substrate or the depositor head follows the path. In one embodiment of the method for reducing non-uniformity of a film produced by atomic layer deposition, the atomic layer deposition system comprises an XY motion device operably coupled to the substrate or the depositor head, and the XY motion device moves such that the position of the substrate relative to the depositor head varies in both the X direction and the Y direction when the substrate or the depositor head follows the path. In one embodiment of the method for reducing non-uniformity of a film produced by atomic layer deposition, the atomic layer deposition system comprises an XY motion device operably coupled to the substrate, and the XY motion device moves such that the position of the substrate relative to the depositor head varies in both the X direction and the Y direction when the substrate follows the path. In one embodiment of the method for reducing non-uniformity of a film produced by atomic layer deposition, the substrate is positioned on a substrate plate connected to the XY motion device. In one embodiment of the method for reducing non-uniformity of a film produced by atomic layer deposition, the atomic layer deposition system comprises an XY motion device operably coupled to the depositor head, and the XY motion device moves such that the position of the substrate relative to the depositor head varies in both the X direction and the Y direction when the depositor head follows the path. In one embodiment of the method for reducing non-uniformity of a film produced by atomic layer deposition, the path has a shape selected from the group consisting of closed shapes having a plurality of line segments, open shapes having a plurality of line segments, and wave shaped. In one embodiment of the method for reducing non-uniformity of a film produced by atomic layer deposition, the path has a rectangular shape.

Referring now to FIGS. 2-4, one non-limiting example embodiment of an atmospheric-pressure spatial atomic layer deposition system 10 that includes various aspects of the present disclosure is shown. The atomic layer deposition system 10 includes a distributor 12 with a zoned ALD precursor gas distributor 16, a substrate plate 18, a base plate 20, an X-axis linear motion stage 22, a Y-axis linear motion stage 23, and a controller 26. The atomic layer deposition system 10 has a frame comprising first and second upstanding support legs 32a, 32b that are spaced apart from one another above a stand surface. The first and second upstanding support legs 32a, 32b support a top plate 34 horizontally in an elevated position. The atomic layer deposition system 10 is capable of conformally coating a growth portion of a build substrate, which can be a silicon wafer or a substrate composed of some other inorganic or organic material, with an ultra-high aspect ratio sub-nanometer precision film of an ALD material one atomic layer at a time. The atomic layer deposition system 10 operates by sequentially exposing the growth portion of the build substrate to separate zones of the first and second ALD precursor gases so that space-sequenced and self-limiting surface reactions can proceed as the growth portion moves back-and-forth through the spatially isolated ALD precursor gas zones. A wide variety of products can be manufactured wholly or partially with the atomic layer deposition system 10 including, for example, photovoltaic and printed electronic devices. The top plate 34 carries the zoned ALD precursor gas distributor 16 and is supported in its elevated position on the upstanding support legs 32a, 32b. The top plate 34 is tiltable and, as such, has the potential to control the tilt of the gas distributor 16. The top plate 34 is tiltable in that the plane of the top plate 34 established by the longitudinal and lateral axes can be tilted about both axes. An underside of the top plate 34 is supported by first and second linear actuators L4, L5 which include first and second motors. The first and second linear actuators L4, L5 individually and in coordination with each other, allow the top plate 34 to be tilted about each of its axes to achieve precision movement in three-dimensions.

The zoned ALD precursor gas distributor 16 includes a gas manifold 56 and a depositor head 58. The gas manifold 56 is in fluid communication with sources of a first ALD precursor gas, a second ALD precursor gas, an inert gas, and a vacuum source to provide suction for the exhaust of unreacted precursor gases and the inert gas. The depositor head 58 is secured to the delivery end of the gas manifold 56, although in other implementations the gas manifold 56 and the depositor head 58 may be integrally formed. The depositor head 58 may be constructed from stainless steel or some other chemically inert material that does not react adversely with the precursor gases during delivery. Mass flow controllers may be attached to the gas manifold 56 to control the flow of the first and second ALD precursor gases as well as the flow of the inert gas.

Looking at FIG. 3, the depositor head 58 has an active surface 62 configured to discharge at least one linear flow of the first ALD precursor gas 64, at least one linear flow of the second ALD precursor gas 66, and at least one linear flow of the inert gas 68 that separates the linear flow of the first ALD precursor gas 64 and the linear flow of the second ALD precursor gas 66, as shown in FIG. 3. The linear flow of the first ALD precursor gas 64, the linear flow of the second ALD precursor gas 66, and the linear flow of the inert gas 68 are parallel to each other; however other arrangements are possible. Since the linear flows of the ALD precursor gases 64, 66 are separated and flow isolated by the linear flow of the inert gas 68, the linear flow of the first ALD precursor gas 64 and the linear flow of the second ALD precursor gas 66 establish first and second ALD precursor gas zones, respectively, while the linear flow of the inert gas 68 establishes an inert gas curtain. More than one linear flow of the first ALD precursor gas and more than one linear flow of the second ALD precursor gas may be delivered from the active surface 62 of the depositor head 58 so long as the linear flows of the first and second ALD precursor gases alternate across the active surface 62 with each pair of adjacent linear flows of the first and second ALD precursor gases being separated by a linear flow of the inert gas to ensure the establishment of respective ALD precursor gas zones. Each linear flow of the various ALD precursor and inert gas can be controlled by its own mass flow controller.

As shown in FIG. 3 and referred to as a “showerhead” delivery arrangement, the active surface 62 of the depositor head 58 may define a central elongated channel 70 that discharges a linear flow of the first ALD precursor gas 64 through pinholes 70h. The active surface 62 also defines a second elongated channel 72 on one side of the central elongated channel 70 and a third elongated channel 74 on the other side of the central elongated channel 70. The second elongated channel 72 extends parallel to the central elongated channel 70 and discharges a linear flow of the second ALD precursor gas 66 through pinholes 72h. The third elongated channel 74 extends parallel to the central elongated channel 70 and discharges a linear flow of the second ALD precursor gas 66 through pinholes 74h. To keep the linear flows of the first and second ALD precursor gases isolated into their respective ALD precursor gas zones, a fourth elongated channel 76 is defined by the active surface 62 between the central elongated channel 70 and the second elongated channel 72 wherein the fourth elongated channel 76 discharges a linear flow of the inert gas 68 through pinholes 76h, and a fifth elongated channel 78 is defined by the active surface 62 between the central elongated channel 70 and the third elongated channel 74 wherein the fifth elongated channel 78 discharges a linear flow of the inert gas 68 through pinholes 78h. Each of the fourth and fifth elongated channels 76, 78 extends parallel to each of the central, first, and second elongated channels 70, 72, 74 and is bound on each side by a pair of elongated vacuum ports 80a, 80b, 80c, 80d. The vacuum ports 80a, 80b, 80c, 80d communicate with exhaust lines to remove the inert gas and any un-reacted ALD precursors gases. All of the elongated channels 70, 72, 74, 76, 78 run parallel to each other.

The active surface 62 of the depositor head 58 also defines a continuous peripheral border channel 82 that surrounds and encloses all of the other channels 70, 72, 74, 76, 78. The peripheral border channel 82 includes first and second elongated side channel portions that run parallel to the other elongated channels 70, 72, 74, 76, 78. Additionally, the peripheral border channel 82 includes first and second elongated bridge channel portions that run perpendicular to the elongated channels 70, 72, 74, 76, 78 and connect with the elongated side channel portions 82a, 82b to complete the continuous track of the peripheral border channel 82. The peripheral border channel 82 discharges a flow of the inert gas and, more specifically, the four channel portions of the peripheral border channel 82 discharge corresponding linear flows of the inert gas through pinholes 82h. In that regard, a linear flow of the inert gas is located on each side of the second and third elongated channels 72, 74 opposite the fourth and fifth elongated channels 76, 78, respectively, such that an inert gas curtain is present on each side of the second ALD precursor gas zones established by the linear flows of the second ALD precursor gas discharged from the second and third elongated channels 72, 74.

The X-axis linear motion stage 22 and the Y-axis linear motion stage 23 move the substrate plate 18 relative to the depositor head 58 to facilitate the ALD process. The central block 92 upon which the base plate 20 is disposed is mounted to a mobile table connected to the X-axis linear motion stage 22. A number of constructions of the X-axis linear motion stage 22 and the Y-axis linear motion stage 23 are permitted and would work within the atomic layer deposition system 10. In one non-limiting embodiment, the X-axis linear motion stage 22 and the Y-axis linear motion stage 23 preferably have sub-micron resolution, or minimum incremental movement, typically on the order of 5 to 10 nanometers, and a maximum travel speed of 2 meters per second, along with sub-micron repeatability and sub-10-micron horizontal and vertical straightness. Commercially available linear motion stages can satisfy these performance characteristics.

The controller 26 is electrically connected to the X-axis linear motion stage 22, the Y-axis linear motion stage 23, and the mass flow controllers (and associated valves) of the gas manifold 56. The controller 26 may be a computer terminal that is dedicated to operating the atomic layer deposition system 10 or some other programmable device that can receive input data, execute programmed instructions, and export output data. A programming language, such as Python, may be used to establish an integrated application program interface through which all of the components connected to the controller 26 can be communicated with and controlled through appropriate communication protocols.

The atomic layer deposition system 10 can be operated to grow a precision film of the ALD material layer-by-layer onto the growth portion of the build substrate while monitoring and, if necessary, adjusting a relative X-Y position of the depositor head 58 and the substrate plate 18 in real-time. To operate the atomic layer deposition system 10, the linear flow(s) of the first ALD precursor gas 64, the linear flow(s) of the second precursor ALD gas 66, and the linear flow(s) of the inert gas 68 are discharged from the active surface 62 of the depositor head 58 to establish the precursor ALD gas zone(s) and the inert gas curtain(s). The discharge of these linear gas flows is controlled by the controller 26 through the mass flow controllers. At the same time, the X-axis linear motion stage 22 and the Y-axis linear motion stage 23 comprising the XY motion device are controlled by the controller 26 to cause the substrate plate 18 to move in a path relative to the depositor head 58. The relative movement between the substrate plate 18 and the depositor head 58 alternately exposes the growth portion of the build substrate 30 to the first and second ALD precursor gases to deposit the ALD material film one atomic monolayer at a time. In another embodiment of the atomic layer deposition system, the X-axis linear motion stage 22 and the Y-axis linear motion stage 23 comprising the XY motion device are connected to the depositor head 58.

The first precursor gas and the second precursor gases used during ALD processing may vary depending on the composition of the ALD material film being deposited. The first precursor gas may, for example, be an organometallic gas, and the second precursor gas may be an oxidant gas. In one implementation, the ALD material film grown on the build substrate may be a metal oxide such as titanium dioxide (TiO₂), zinc oxide (ZnO), tin oxide (SnO₂), or aluminum oxide (Al₂O₃). To deposit TiO₂, ZnO, SnO₂, or Al₂O₃ by SALD, the first precursor gas (an organometallic gas) may be titanium tetraisoproxide (TTIP) or tetrakis(dimethylamino)titanium (TDMAT) for TiO₂, diethylzinc (DEZ) for ZnO, tetrakis(dimethylamido)tin (TD-MASn) for SnO₂, and dimethylaluminum isopropoxide (DMAI) or trimethyl aluminum (TMA) for Al₂O₃, and the second precursor gas (an oxidant gas) in each instance may be distilled water. The inert gas used to separate and isolate the first precursor gas and second precursor gas may be nitrogen (N₂). Of course, other ALD precursor gases and inert gases may be employed to form any of the aforementioned metal oxide films as well as other compositions of the ALD material. The atomic layer deposition system described herein and the ways in which the ALD system is used are not limited to any particular ALD precursor gases, inert gases, or compositions of the deposited ALD material film.

The atomic layer deposition system 10 can be operated to grow a precision film of the ALD material wherein the film has a “uniform” thickness on the substrate. A “uniform” thickness means having a non-uniformity of less than a predetermined percentage where non-uniformity is calculated as ((maximum film thickness−minimum thickness) divided by (two multiplied by mean thickness))×100. In certain embodiments, the atomic layer deposition system 10 produces a film having a non-uniformity of less than ±30%, or less than ±20%, or less than ±15%, or less than ±10%, or less than ±5%.

### Example

The following Example is provided in order to demonstrate and further illustrate certain embodiments and aspects of the present invention and is not to be construed as limiting the scope of the invention. The statements provided in the Example are presented without being bound by theory.

### Overview of Example

A customized atmospheric-pressure spatial atomic layer deposition (AP-SALD) system was designed and implemented, which enables mechatronic control of key process parameters, including gap size and parallel alignment. A showerhead depositor delivered precursors to the substrate while linear actuators and capacitance probe sensors actively maintained gap size and parallel alignment through multiple-axis tilt and closed-loop feedback control. Digital control of geometric process variables with active monitoring was facilitated with a custom software control package and user interface. AP-SALD of TiO₂ was performed to validate self-limiting deposition with the system. A novel multi-axis printing methodology was introduced using x-y position control to define a customized motion path, which enabled an improvement in the thickness uniformity by reducing variations from 8% to 2%. This mechatronic system enables experimental tuning of parameters that can inform multi-physics modeling to gain a deeper understanding of AP-SALD process tolerances, enabling new pathways for non-traditional SALD processing that can push the technology towards large-scale manufacturing.

### 1. Introduction

Atomic layer deposition (ALD) is a nanomanufacturing technique that is widely used to control surfaces and interfaces and has been commercialized, most notably, by the semiconductor industry. ALD utilizes self-limiting chemical reactions to create thin films with atomic-scale control, enabling conformal coating of high-aspect ratio surfaces [Ref. 1,2]. The substrate is exposed to alternating precursor pulses (see FIG. 1), which are separated temporally to deposit films with sub-nanometer precision. However, to effectively separate the precursors with respect to time, a purging step is introduced between the reactants, resulting in relatively slow cycle times. In addition, current ALD equipment relies on vacuum systems that are energy and cost intensive to scale, limit compatibility with substrates that are sensitive to vacuum environments, and are difficult to interface with continuous (as opposed to batch processing) manufacturing lines. As a consequence, while ALD has been commercialized for low-volume, high-value applications [Ref. 3], there is limited commercialization in higher-volume, lower-cost applications, such as clean energy technologies, catalysis, and biomedical applications.

To overcome these challenges, spatial atomic layer deposition (SALD) delivers the precursors via zones with spatial separation rather than sequential pulse/purge steps [Ref. 4-7] A relative motion path between the zones and substrate exposes the surface to the alternating precursors, as shown in FIG. 1 panel b. Delivery of the ALD reactants in isolated spatial zones that are separated by inert gas regions eliminates the need for time-expensive purging steps. As a result, significantly faster film growth times, in the range of single nm s⁻¹ compared to several hundredths of nm s⁻¹ for conventional ALD, have been demonstrated [Ref. 8,9]. Additionally, SALD can be performed at atmospheric pressure, which eliminates the need to scale-up vacuum systems, opens a wider range of substrate compatibility, and enables integration into current manufacturing processes. Because of these benefits, AP-SALD holds promise to address the large-scale manufacturing needs of interfacial engineering at the nanoscale.

A technique known as close-proximity SALD uses a depositor to create precursor zones that are separated with inert gas curtains and exhaust lines to isolate the precursors and prevent transport of oxygen from the surroundings. The substrate is brought in close proximity to the depositor and then moved relative to the zones, exposing the substrate to alternating precursors and depositing a film (FIG. 1 panel b). Among the state-of-the-art close-proximity AP-SALD systems, multiple designs have been demonstrated for both batch and roll-to-roll [Ref. 10,11] processes, including rotating disc [Ref. 8,12,13], rotating drum [Ref. 6,14,15], linear unidirectional [Ref. 10, 16-26], and linear multi-directional [Ref. 27,28]. These various designs have been used to deposit films on multiple substrates, including silicon [Ref. 8, 12-14,17,22,27,28], glass [Ref. 9,17,20-22,29,30], polymers [Ref. 10,11,14,15,19,21-23], and fabrics [Ref. 18,24]. Notably, AP-SALD has been industrialized for batch passivation of solar cells [Ref. 6].

Typically, close-proximity AP-SALD systems have fixed geometric parameters such as the gap size and relative alignment between the depositor and substrate (FIG. 1 panel c). While many systems have been designed to alter these parameters manually, there are few examples where integrated sensors and actuators are used to actively monitor and adjust geometric process parameters in real time. Therefore, there is limited scientific understanding of the importance of tolerances to these adjustable process parameters. This lack of understanding yields uncertainty in optimized design constraints and bounds on the sample geometry.

The influence of variations of gap size and alignment during close-proximity AP-SALD is particularly interesting since ALD processes have been proposed for a wide range of applications where the bulk substrate is not a planar geometry. For example, anti-corrosive coatings could be used for automobiles [Ref. 31], and anti-biofouling coatings could be used for marine vessels [Ref. 32]. Previous work has investigated the use of AP-SALD on silicon (Si) trenches [Ref. 19], Si pillars [Ref. 28], textured Si [Ref. 29] and nanowires [Ref. 33-35], but the characteristic length scale of these features is typically much smaller than that of the bulk substrate. A unique solution to enable coating of challenging samples is to design the depositor geometry to match that of a specific sample, as shown by Toldra-Reig et al. [Ref. 36]. Therefore, various depositors have been 3D printed for specific applications, but the complexity of this approach grows greatly as the substrates become larger and require design flexibility.

One could envision an AP-SALD “paint brush” that could coat sizeable surfaces that are too large to fit into a conventional ALD chamber and too complex to be uniformly coated by the state-of-the-art close-proximity systems. Mousa et al. demonstrated a similar concept on a car windshield, using in loco conventional ALD [Ref. 37] rather than SALD. The foundation for this approach using close-proximity AP-SALD has been demonstrated with a “pen” that allows localized printing with a line width on the order of millimeters [Ref. 27,28]. In the future, one could design a variety of close-proximity AP-SALD systems to coat customized geometries over a range of length scales; however, there is limited understanding of the acceptable tolerances for the AP-SALD geometric parameters needed to achieve uniform films, including gap size and relative alignment, and how they are coupled with gas flow parameters, such as flow rates and pressure. Therefore, there is a need to understand the extent to which a sample geometry can vary beneath an AP-SALD depositor and how to monitor and control the process to yield quality, uniform films over large areas.

In this Example, a customized AP-SALD system with mechatronic control and in situ sensing of the process parameters has been designed and built. Herein, we discuss the design of this system with closed-loop process control over a range of process variables, most notably gap size, alignment, and relative motion. We then demonstrate and validate our system by depositing titanium dioxide (TiO₂) films using titanium(IV) isopropoxide (TTIP) and deionized (DI) water as the metal and oxidant precursors, respectively. Finally, we investigate the effects of multi-axis printing on film uniformity.

### 2. System Design

A close-proximity, linear travel, mechatronic AP-SALD system was designed and manufactured with closed-loop control over the key geometric parameters of gap size, alignment, and relative motion (see FIG. 2). A showerhead depositor and substrate plate form gas/precursor zones for the process region (see FIG. 2 panel a). Capacitance probe sensors C1, C2, C2 (FIG. 2 panel b) measure the gap size and alignment, while linear actuators L1, L2, L3, L4, L5 and a pivot point P (FIG. 2 panel a, panel b) are used to maintain the desired geometry by adjusting the orientation of the top plate 34 and substrate plate 18. Two precision motorized stages 22, 23 control the substrate velocity and positioning (FIG. 2 panel a). Independent control of gas flow rates and pressure is facilitated by a fluid control system (see Section 5.1 below). Digital control of process variables with active monitoring is facilitated with a controller 26 with a custom software control package and user interface.

### 2.1. Process Region

The process region is defined as the volume of space between the bottom of the depositor 12 and the top of the substrate plate 18, which is comprised of the various gas zones (see FIG. 3). To achieve self-limiting, conformal ALD within an AP-SALD system, the process region must be isolated from ambient oxygen and water vapor, while also preventing cross-contamination of the precursor regions. A depositor 12 was designed with a showerhead geometry and mounted to a top plate 34 (FIG. 2 panel a and FIG. 3 panel a). The input gases are directed through the depositor manifold 56, which has internal flow channels to distribute the gases to their respective zones (see Section 5.2 below). The pinholes create four distinct zone categories to establish an isolated and defined process region—metal precursor, water precursor, outer nitrogen, and inner nitrogen (FIG. 3 panel c). Further details on the gas delivery and heating systems are provided in Section 5.1 below. Exhaust lines remove excess nitrogen gas, unreacted precursors, and reaction byproducts from the process region. The target substrate is introduced into the process region by mounting it to the substrate plate 18 via a vacuum chuck.

We note that while the geometric dimensions of the pinholes on the depositor are fixed, the spatial variations in gas pressure, composition, and velocity will depend on the detailed fluid mechanics occurring within the process region [Ref. 26,38-42]. These process region metrics will be directly influenced by process variables including gas flow rates, exhaust pressure, gap size, alignment, and relative motion. Previous close-proximity systems have demonstrated control over the gas flow rates and exhaust pressures [Ref. 10,17,19,22,25,26,43], but few have implemented experimental, closed-loop control over the geometric parameters (e.g., gap size and alignment changes during the deposition process), which motivated the development of the mechatronic AP-SALD system described in this Example.

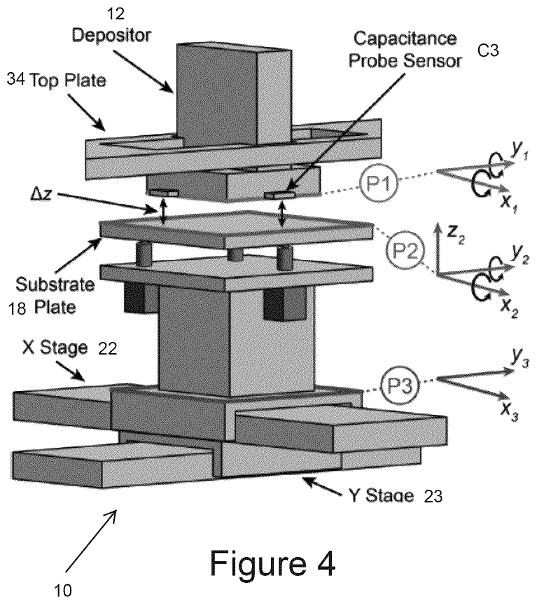

When investigating control of these geometric parameters, three planes are critical to the deposition process (P1, P2, and P3 in FIG. 4). P1 is defined as the bottom surface of the depositor 12 (FIG. 4) from which the precursors exit the manifold. This plane defines the upper surface of the process region. P2 is the top surface of the substrate plate 18 (FIG. 4), which defines the lower surface of the process region. Finally, the precision motorized stages (X and Y in FIGS. 2 and 4) define the third plane (P3 in FIG. 4), which is the plane of motion for the substrate plate 18. We note that in theory, two of these three planes could be rigidly fixed and assumed to be parallel. However, this would not enable the system to compensate for any manufacturing tolerances or drift arising from uncontrolled mechanical or thermal changes. Furthermore, the ability to study AP-SALD under conditions where all three planes may be misaligned allows for future investigations of more complex system topologies such as macroscopically curved substrates. For example, an AP-SALD “paint brush” depositor could be mounted to a robotic arm in a manufacturing plant to dynamically adjust the gap size, alignment, and relative motion on the surface of a large non-planar object such as a vehicle frame.

If the relationships between these three planes of interest are not actively monitored and controlled, cross contamination between the metal and water precursor zones can occur, resulting in unintended chemical vapor deposition (CVD) on the substrate surface. Furthermore, within a large-scale manufacturing context, precursors could leak from the process region to the ambient environment posing a safety risk to workers. Our system integrates sensors, actuators, and controls to measure, alter, and maintain desired system geometries, as discussed in the following sections.

### 2.2. Sensors

Within close-proximity SALD systems, the gap size (Δz in FIG. 4) is defined as the distance between the depositor and the substrate plate. Within literature, this process parameter is often quoted as a single number or not reported at all [Ref. 8,10,14-23,25-28], thus assuming perfect alignment. However, the gap size can vary in both space and time if active control of parallel alignment is not ensured. Despite this fact, many systems rely on static or passive control of the gap size.

To this end, the described system incorporates three capacitance probe sensors (C1, C2, and C3 in FIG. 2) to measure the distance between the depositor (P1 in FIG. 4) and substrate plate (P2). Capacitance probe sensors were chosen because they are rated to operate at elevated temperatures, as the system is heated during operation (further details in Section 5, Experimental Section). While the capacitance probes perform well for this Example, there are some requirements to enable their use. As the operating principle requires two electrically conductive planes, the capacitance probe sensors must be electrically isolated from the mounting hardware and depositor. The conductivity requirements of the substrate depend on its geometry. If the substrate is larger than the linear distance between the sensors, the substrate would typically need to be conductive to provide the second plane to form a capacitor. However, if using a sufficiently thin substrate, a large non-conductive substrate could also be used as it would only alter the dielectric constant between the two planes. Furthermore, if the sample is smaller than the distance between the sensors, only the substrate plate must be conductive.

The sensors are mounted on separate sides of the depositor such that they lie within P1 in FIG. 4. With three gap size measurements, the plane equation for the substrate plate (P2) relative to the depositor surface (P1) can be calculated using the system of equations shown in Section 5.3 below. In addition, the plane transformation to achieve parallel alignment of the substrate plate and depositor at a given gap size can be calculated using matrix manipulations and Cramer's rule (further details in Section 5.3 below). These sensors, combined with the control software described in Section 2.4, allow for high-resolution monitoring in both the spatial (<50 nm) and temporal (<100 ms) domains.

### 2.3. Actuators

The sensors described above allow for the measurement of the current gap size and alignment. Given these values, one can calculate the needed changes to the system configuration to achieve a desired gap size and alignment during a deposition process. A combination of linear actuators L1, L2, L3, L4, L5, a pivot point P, and precision motorized stages 23, 23 are used to control the position and orientation of the depositor 12 and substrate plate 18 during the deposition process.

The substrate plate 18 rests upon three stepper-motor-driven linear actuators (L1, L2, and L3 in FIG. 2) which constitute the substrate alignment system. The three points of contact define the substrate plane (P2 in FIG. 4). This alignment system controls the orientation of the substrate plate (rotation about x₂ and y₂ in FIG. 4) and vertical position (along z₂ in FIG. 4). The linear actuators can be driven simultaneously or independently allowing for precise control of both the gap size and relative orientation of planes P1 and P2.

The top plate 34, to which the depositor 12 is rigidly mounted (FIG. 2 panel a), rests upon its own alignment system. Three supports define its position—one passive pivot point and two stepper motor-driven linear actuators (P, L4, and L5 in FIG. 2). Controlling the top plate allows for the angular orientation of P1 (rotation about x₁ and y₁ in FIG. 4) to be adjusted and controlled relative to P3.

The substrate alignment system is mounted on two orthogonal precision motorized stages to 22, 23 control the x₃ and y₃ position, velocity, and acceleration of the substrate during a deposition process (FIG. 3 panel a). The use of a two-axis stage configuration, as opposed to the more common uniaxial motion (along the x-axis), enables more complex substrate paths, as will be discussed in Section 3.2. For further details on the linear actuators and motorized stages, please see Section 5, Experimental Section, below.

### 2.4. Controls

The sensors and actuators described above provide the inputs and outputs, respectively, to a control software package in a controller 26. To develop an integrated control software, Python 3 was selected, as it allows for customizable user interface design, parallel processing with multi-threading, a wide range of communication protocols, and many open-source controls packages. A graphical user interface (GUI) enables the user to actively control and monitor the various system parameters such as valve actuation, gas flow rates, process temperatures, gap size, alignment, substrate position, and velocity in real time. The following sections demonstrate experimental control with closed-loop feedback over the gap size, alignment, and relative motion of the close-proximity AP-SALD system.

### 2.4.1. Stationary Alignment Control

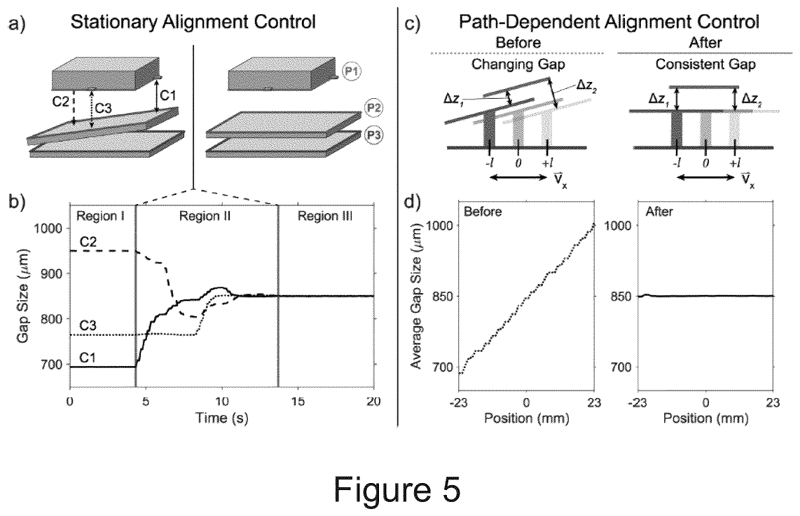

As previously discussed, the alignment of the substrate plate (P2) relative to the depositor (P1) is important for maintaining a defined process region. While the motorized stages are held stationary, the substrate alignment system can adjust the substrate position and orientation with real-time measurements from the capacitance probe sensors. This closed-loop feedback allows for automatic alignment of P2 and P1 for a given gap size. An automated example of the process-region alignment can be seen in FIG. 5 panels a-b, where the substrate was initially misaligned and then the alignment was corrected to a specified gap size of 850 μm using closed-loop control. As a proxy for the misalignment of two planes, one can compare in FIG. 5 panel b the range of the gap sizes measured by the capacitance probes (C1-C3) before (Region I) and after (Region III) alignment. Initially, the range of measured gap sizes was 256 μm, indicating non-parallel alignment. After the process-region alignment, this value was reduced to 1.44 μm, demonstrating the effectiveness of the mechatronic system control. The alignment time can vary based on the initial misalignment conditions, but typically is completed within 10 to 15 seconds.

### 2.4.2. Path-Dependent Alignment Control

While stationary alignment control is necessary for SALD, it does not guarantee that a consistent gap size is maintained between the depositor and substrate during the deposition process. This is because the depositor (P1) may be misaligned to the plane of motion established by the linear stage (P3). If all three planes (P1, P2, and P3) are not aligned, the average gap size may increase or decrease during a reciprocating printing motion. This is illustrated schematically in FIG. 5 panel c, where the average gap size (Δz₁, Δz₂) varies as a function of the translational position of the x-stage, which is responsible for the back-and-forth printing motion. The reason for this variation in gap size with respect to substrate position is that while P1 and P2 were brought into parallel alignment during the stationary alignment process, they are not necessarily parallel to P3 along the path of motion, as discussed in Section 2.1.

FIG. 5 panel d shows experimental measurements from the capacitance probe sensors when P1 and P2 have been brought into alignment using the stationary alignment control algorithm described above, but they are not yet aligned to P3. As a result, the range of average gap size along the motion path before performing path-dependent alignment control is approximately 320 μm (left panel of FIG. 5 panel d). The angle of the misaligned depositor (P1) relative to the plane of motion (P3) can be calculated using the change in average measured gap size over the known linear distance of travel, resulting in a calculated angle of approximately 0.4 degrees. While this may seem like a small misalignment error, the combination of small gap sizes and large deposition motions can result in crashing of the depositor and substrate, which is unacceptable within a manufacturing process. Moreover, as discussed in Section 2.1, even if a crash does not occur, dynamic changes in the gap size during printing may be undesirable because of the concomitant effects on gas pressure, composition, and velocity within the process region [Ref. 26,38-42].

To correct for the P1-P3 misalignment, the path-dependent alignment control algorithm follows a two-step procedure. In the first step, the capacitance probe sensors are used to measure the variations in gap size along the motion path. In the second step, the depositor is brought into alignment with the plane of motion established by the linear stages. This alignment procedure is accomplished by first calculating the required angular orientation of the depositor (P1) with respect to the orientation of the plane that defines the motion path (P3). The needed adjustment to bring P1 and P3 into alignment is accomplished by the linear actuators that control the orientation of the top plate (L4 and L5 in FIG. 2 panel a) as described in Section 2.3. After bringing P1 and P3 into parallel alignment, the stationary alignment control process is repeated to realign P1 and P2, which ensures that all three planes are parallel throughout the motion path. FIG. 5d shows that the range in the average gap size along the motion path after path-dependent alignment is significantly reduced to approximately 4 μm, which corresponds to a misalignment angle of approximately 0.005 degrees.

In summary, the function of path-dependent alignment control is to generate a “map” of relative alignment along the full motion path, and then adjust the actuators in a manner that maintains parallel alignment throughout this motion path. In the current study, all three planes of interest (P1, P2, and P3) are flat, and therefore, a singular configuration of the actuators is sufficient to ensure parallel alignment throughout the full motion path. Having a mechatronic SALD system could also enable non-planar motion paths, for example, to coat curved surfaces. The demonstration of path-dependent alignment control in this Example represents a first step toward this vision, where the motion path is flat. However, path-dependent alignment control could be performed by first using sensors to map the variations of substrate topography (P2) along a printing motion path (P3). This could then be used to define a tool path, analogous to CNC control of milling machines, of the depositor motion and alignment (P1). Once the predicted tool path is defined, closed loop control in real time could be further implemented to adjust for deviations in parallel alignment (i.e., drift), which will be discussed in the subsequent section.

### 2.4.3. Drift Control

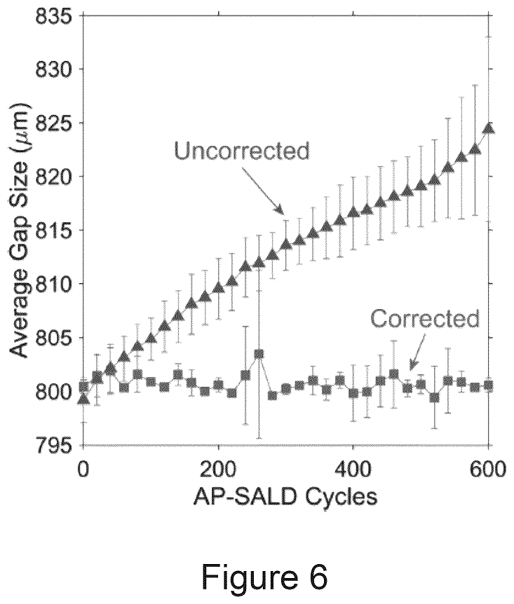

The combination of stationary and path-dependent alignment control produces a system with all three planes (P1, P2, and P3 in FIG. 4) aligned so that the gap size is consistent during a printing process. However, machining and process tolerances and environmental variables (such as thermal expansion) in the manufacturing setting can cause the gap size to drift during a deposition process. With the mechatronic system described, the gap size and alignment can be monitored and corrected throughout a deposition process with closed-loop feedback. In FIG. 6, we show that the average gap size drifted ˜25 μm away from the set point of 800 μm over 600 AP-SALD cycles without active control. With closed-loop control, the gap size was corrected every 20 cycles, resulting in an average gap size that did not vary more than 4 μm from the set point. While the exact drift for a given system will be largely dependent on its design and process conditions, we demonstrate that with closed-loop control of the effects of drift on the gap size and alignment can effectively be reduced during an AP-SALD process.

### 3. System Demonstration

To demonstrate the ability of the AP-SALD system to deposit films in a self-limiting ALD mode, titanium dioxide (TiO₂) films were grown using titanium(IV) isopropoxide (TTIP) and deionized (DI) water as the metal and oxidant precursors, respectively. TTIP was selected for its relative safety (non-pyrophoric, non-corrosive), low cost, and established ALD behavior [Ref. 30,44-53]. For each deposition, the substrate was moved at a velocity of 20 mm s⁻¹ resulting in a cycle time of 4.6 seconds. The total process time linearly increases with the number of cycles. A full description of the deposition parameters, including temperatures, flow rates, substrate velocity/position, is provided in Section 5, Experimental Section, below.

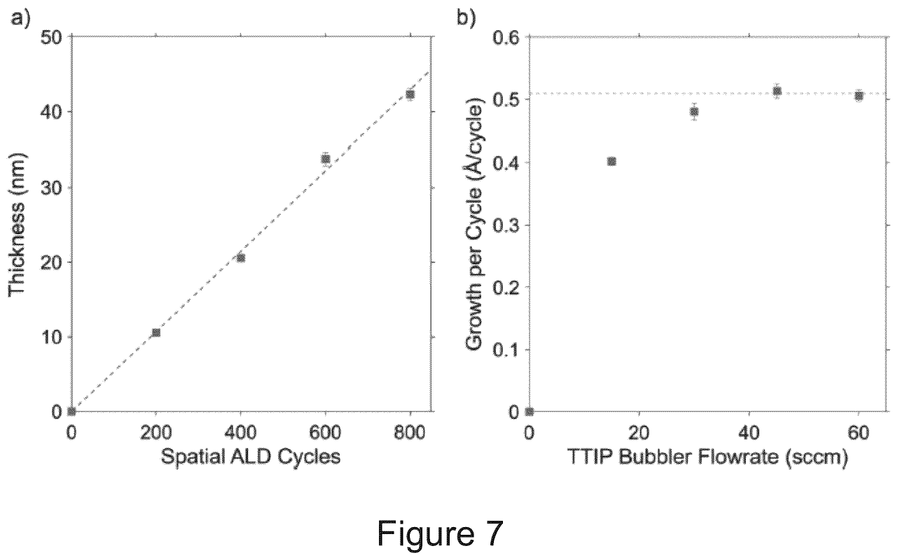

To characterize the film growth rate, ellipsometry measurements were performed at 20 separate locations along the substrate within the deposition region. We note that geometry of the deposited region depends on the range of linear travel of the x-stage during the back-and-forth motion of the printer, and therefore the thickness measurements were collected within the deposition region to avoid edge effects from overlapping exposures (see Section 5.4 below). The films exhibit linear and saturated growth behavior that is characteristic of well-behaved ALD processes (see FIG. 7). A linear increase in film thickness with respect to cycle number was demonstrated over 800 cycles (FIG. 7 panel a) resulting in a calculated growth per cycle (GPC) of 0.54 Å cycle⁻¹. Furthermore, the growth per cycle was observed to saturate at 0.51 A cycle⁻¹ when the precursor flux (which corresponds to the precursor dose in traditional ALD) was increased by increasing the flow rate through the TTIP bubbler (FIG. 7 panel b). The measured growth rate of this AP-SALD system lies within the reported range of values in the literature which is =0.04-1 A cycle⁻¹ for SALD [Ref. 30,44-48], and =0.1-0.5 A cycle⁻¹ for traditional ALD [Ref. 49-53].

### 3.1. Film Characterization

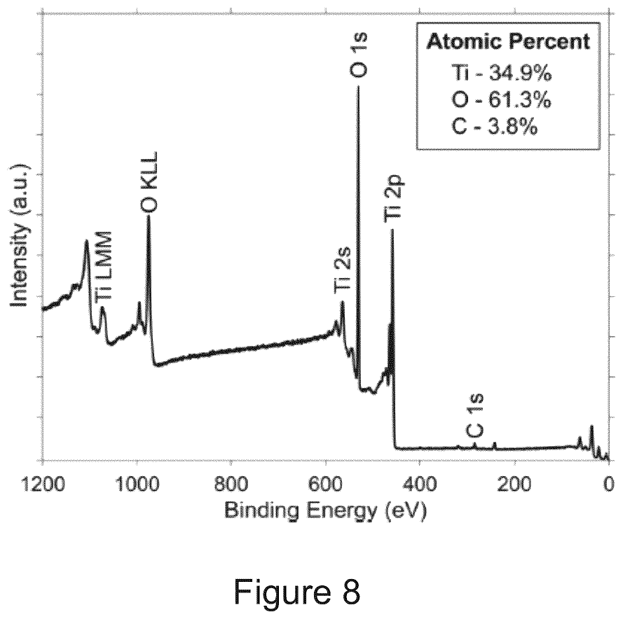

To characterize the film stoichiometry, X-ray photoelectron spectroscopy (XPS) was performed on a TiO₂ film that was deposited using 600 AP-SALD cycles, which corresponds to a thickness of 32 nm as measured by ellipsometry (see FIG. 8). As seen in the inset, the actual titanium (Ti) to oxygen (O) ration is approximately 1:2. The small variation from the ideal is likely due to the known preferential sputtering of 0 within TiO₂ [Ref. 54]. The film shows no evidence of pinholes, as there are no silicon (Si) peaks present, even after three minutes of Argon (Ar) sputtering, which corresponds to =3 nm of film removed. A small percentage of carbon (C) is observed in the film which is consistent with previously reported TiO₂ films deposited using TTIP [Ref. 55].

### 3.2. Multi-Axis Printing

Traditionally, linear-motion SALD systems use either continuous translation in one direction, or a back-and-forth reciprocating translation along a single axis [Ref. 10,16-26]. A new type of SALD system design has been introduced that allows for multi-axis printing of SALD patterns, allowing for area-selective deposition in the patterned regions [Ref. 27,28]. Through miniaturization of a close-proximity SALD head, an “SALD pen” can be fabricated, which allows for customizable and free-form patterning of the deposited material on the substrate. However, to our knowledge, in larger-scale SALD depositors, multi-axis printing has not been previously demonstrated. Herein, we demonstrate the potential of multi-axis printing to compensate for non-uniformities in the deposited material geometry that may arise as a result of the system design. We note that the depositor design in this Example only “prints” material when the substrate is translated along the x-axis. The y-axis motion adjusts the position of the deposited pattern in orthogonal direction but does not actively print new material because of the geometry of the precursor zones.

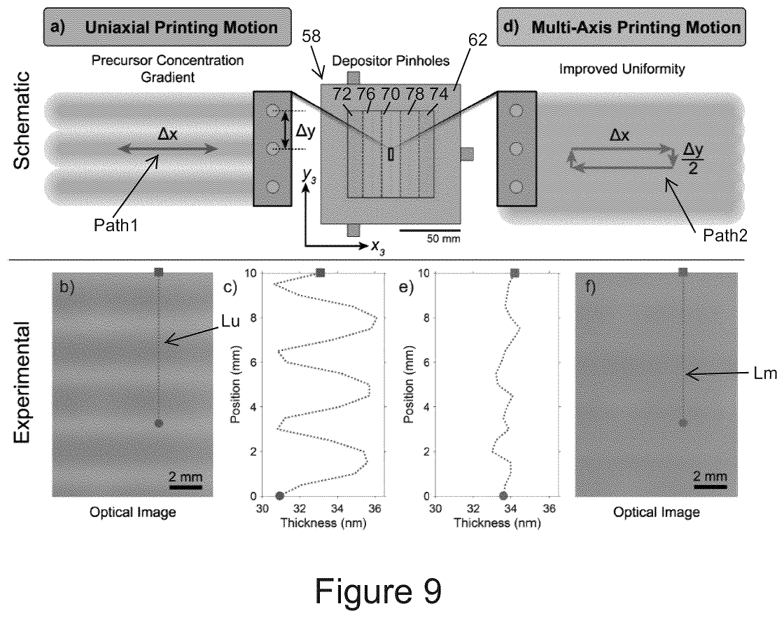

As shown in FIG. 3, our depositor 12 is comprised of a showerhead geometry, which is common in large-area deposition systems as it offers a simple method of distributing the gases over a large substrate area. However, as a result of the pinhole geometry from the showerhead, the localized fluid mechanics within the process region will exhibit spatial variations in the pressure/concentration profile of the precursors as they are transported radially away from the center of a pinhole. As a result of this flow profile, the local precursor concentration will be largest immediately below the pinholes, and concentration gradients will be present in the regions between the pinholes (see FIG. 9 panel a). When using single-axis reciprocating motion Path1 (i.e., along the x₃-axis), the deposited films display periodic variations in the film thickness (FIG. 9 panel b). This variation in concentrations means that portions of the substrate surface may not be exposed to a sufficient precursor dose to fully saturate the ALD growth, resulting in variations in the film thickness.

One potential strategy to reduce the film non-uniformity associated with the pinhole geometry is to decrease the substrate velocity, which would increase the precursor dose to the substrate within the lower concentration regions. To examine this possibility, an experiment was conducted at a lower substrate velocity. However, the periodic variations in film thickness were still observed, while negatively impacting process throughput (see Section 5.8 below). Therefore, there is a need for alternative approaches to improve the film non-uniformities that can occur during close-proximity SALD.

Because TiO₂ has a relatively high index of refraction (n==2.4), the small changes in the film thickness can be seen optically (FIG. 9 panel b). To provide a quantitative measure of the thickness variations, line scans Lu, Lm were performed using spectroscopic reflectometry (further details in Section 5, Experimental Section). When single-axis motion was used along the x₃-axis, the total range of film thickness along the y₃-axis was from 30.6 to 36.1 nm, resulting in a deviation from the average thickness of ±8.22% (FIG. 9 panel c). The correlation between the pinhole spacing (3.175 mm) and the periodicity of the film thickness (=3.25 mm) was also confirmed.

Because of the mechatronic system design, a multi-axis substrate motion path was enabled, which can be used to compensate for the periodic variations described above. A customized motion path was selected based on the pinhole geometry. Specifically, a “box path” pattern Path 2 was programmed using the Python control software package, as shown in FIG. 9 panel d, which introduced new steps along the y₃-axis at the end of each linear motion along the x₃-axis. The magnitude of the y₃-axis steps was calculated to be half of the period of the pinholes and ribbing features (1.5875 mm), such that substrate surface is more uniformly exposed to a saturating flux of precursors. This can be thought of as step toward the envisioned “paint brush” described in Section 1, where the customized motion path can interweave the contact points between the “bristles” of the brush and the substrate. Holding all other parameters the same, the customized motion path resulted in a film that was visually more uniform (FIG. 9 panel f). This improved uniformity was confirmed with a thickness line scan (FIG. 9 panel e). The total range of film thickness along the y₃-axis was from 33.0 to 34.5 nm, resulting in a deviation from the average thickness of ±2.22%, which is a nearly fourfold decrease compared to single-axis printing.

To our knowledge, this is the first demonstration of multi-axis printing using a large-scale showerhead depositor design to achieve more uniform films. Another important factor that would affect this non-uniformity is the specific design of the depositor flow channels. For example, a slotted geometry for the precursor delivery zones with continuous channels would also assist alleviating the non-uniformity associated with the pinholes. However, avoiding a significant pressure drop along a slot can also become challenging when the length of the slot is large, which requires more complicated flow control within the internal flow channels of the depositor. Furthermore, showerhead designs are commonly used within industrial systems for flow distribution and delivery, making their improved implementation of general interest. This Example demonstrates that with mechatronic sensing and control, non-uniformities in the film can be addressed, irrespective of the depositor design.

It is important to note that all the results in Section 3 were performed using the more uniform, multi-axis printing mode, to ensure the most idealized version of SALD possible. A comparison of the bulk TiO₂ films with uniaxial and multi-axis printing is in Section 5.5 below. Furthermore, while a simple “box path” was demonstrated in this study, more complex motion paths could be designed in the future, depending on the specific depositor and substrate geometries. These micro-scale motions could also be combined with more macroscopic patterning in the x-, y-, and z-directions as well as the rotations along these axes, as shown in FIG. 4, which would enable future manufacturing with SALD as a “paint brush” on complex surface topologies.

### 4. Conclusions

In this Example, a mechatronic AP-SALD system was introduced, closed-loop process control was demonstrated, and TiO₂ deposition was performed. Specifically, in this Example:

(1) A mechatronic AP-SALD system was designed and implemented with sensors and actuators that actively measure, alter, and maintain desired system geometries. This novel mechatronic AP-SALD system uses capacitance probes, linear actuators, and motorized stages to actively measure, alter, and maintain desired system geometries during deposition. The geometry of the process region is directly controlled by three planes—the bottom surface of the showerhead depositor, the top surface of the substrate plate, and the plane of motion established by the motorized stages. The time-dependent geometrical relationships between these three key planes of interest (e.g., gap size and alignment changes during the deposition process) can affect the process region size and shape, which then affects the localized fluid mechanics within this region. The three capacitance probe sensors actively measure the gap size between the depositor and substrate plate, defining the relative orientation of the planes. Linear actuators adjust both the position of the depositor and substrate plate to alter the gap size and relative orientation of the planes. Two orthogonal precision motorized stages controlled the x and y position, velocity, and acceleration of the substrate during a deposition process, which enables customized motion paths. An integrated control software was developed using Python 3 to actively monitor and control the geometric process parameters in real-time.

(2) Closed-loop control over the geometric process parameters enables stationary alignment control, path-dependent alignment control, and drift control. The sensors and actuators enable closed-loop control over the key geometrical process parameters of gap size and parallel alignment. Stationary alignment control was performed to bring the substrate into parallel alignment with the depositor within ±1 μm of a desired gap size in 10-15 seconds. Active monitoring of the plane orientations during deposition revealed the need for path-dependent alignment control to bring all three key planes into alignment. Using the sensors, actuators, and closed-loop control, the range of the average gap size during a deposition process of =320 μm (=0.4 degrees) was reduced to =4 μm (=0.005 degrees). After the initial alignment, the orientation of the three key planes can drift during a deposition process, causing the average gap size and orientation to change with time. The mechatronic system effectively limited the drift in the system to less than 4 μm with closed-loop control during the deposition process, compared to =25 μm without correction.

(3) Linear and saturated growth of TiO₂ thin films was demonstrated TiO₂ thin films were deposited and characterized. A linear growth rate was shown to be 0.54 Å cycle⁻¹ and saturated growth of 0.51 Å cycle⁻¹ was demonstrated by varying the TTIP precursor flux to the substrate. XPS was performed to validate the film stoichiometry and continuity.

(4) A novel multi-axis printing strategy was introduced to improve material uniformity. The geometry of the showerhead depositor caused thickness variations in the deposited films when using single-axis substrate motion. A novel multi-axis printing methodology used x-y position control to define a customized motion path, which enabled an improvement in the thickness uniformity. A “box path” motion was designed specifically for the depositor geometry and resulted in a more uniform film by reducing variations from 8% to 2%. This Example only used rectangular motions, but more complex, customized substrate paths could be designed to further increase uniformity. These results demonstrate that utilizing both the X-axis and the Y-axis while printing with atmospheric-pressure spatial atomic layer deposition systems can reduce non-uniformity in deposited films. However, this Example is only one variation of many substrate paths that can be performed. The travel distance, velocities, and order of motions can be optimized for the depositor head in question. In addition, the motions need not be constrained to linear motions. Sinusoidal or wave motions in varying levels of hierarchy in the X-axis and the Y-axis directions can be used to further reduce non-uniformity.

This mechatronic system design will allow tuning of process parameters experimentally, which will enable a deeper understanding of the process-property relationships during SALD. This capability of controlling the process parameters can further inform multi-physics models enabling digital twins.

### 5. Experimental Section

Sensor Details: The capacitance probe sensors used (HPB-75A, Capacitec, Inc.) have a resolution of 24.48 nm with a measurement range of 1.3 to 1270 μm over the temperature range of −73 to 871° C. Further discussion on the capacitance probe sensor calibration procedure is provided in Section 5.6 below.

Actuator Details: The linear actuators used to control the depositor and substrate plate orientations are stepper-motor-driven linear actuators. The three linear actuators (Haydon Kerk 28H47-2.1-915) for the substrate plate (L1, L2, and L3 in FIG. 2 panel b) have a linear resolution of ≈0.2 μm, resulting in an angular resolution of approximately 1.13e-4 degrees and 8.20e-5 degrees about the x₂ and y₂ axes, respectively. The two linear actuators (Standa 8CMA28-10) for the depositor (L4 and L5 in FIG. 2 panel a) have a linear resolution of =0.08 μm, resulting in an angular resolution of 1.03e-5 degrees and 6.22e-5 degrees about the x₁ and y₁ axes, respectively. Commands for each linear actuator are sent to an Arduino board via the Python controls software, which in turn send the appropriate signals to a stepper motor driver for each linear actuator. Both types of linear actuators were driven with 1/16th micro-stepping.

The two, orthogonally installed linear stages (Aerotech PRO165LM-200) control the x₃- and y₃-axis position, velocity, and acceleration of the substrate during a deposition process (X and Y in FIG. 2 panel a). A direct drive motor system was selected for the fast and precise motion over a large range, up to 2 m s⁻¹, ±8 μm, and 200 mm. The linear speed of the stages enables cycle times on the order of tens of cycles per second and areal throughputs less than 1,280 cm² s⁻¹. In addition, the stage selected had small pitch, roll, and yaw error (8.2 arc sec) for stable substrate motion.

Deposition Parameters: SALD of TiO₂ was performed using titanium(IV) isopropoxide (TTIP, min. 98%, Strem Chemicals Inc.) and deionized (DI) water as the metal and oxidant precursors, respectively. The TiO₂ films are deposited on 150 mm test-grade silicon wafers that were positioned on the substrate plate using a customized alignment tool. Across depositions, the substrate was moved consistently at 20 mm s⁻¹ with a travel distance of ±23 mm, resulting in a cycle time of 4.6 seconds and areal throughput of ˜14 cm²s-1. The substrate plate was held at a consistent temperature of 105° C. while the depositor was heated to 115° C. The TTIP bubbler was heated to a temperature of 70° C. and the water bubbler and associated tubing was kept at room temperature, approximately 25° C. A rising temperature gradient from the TTIP bubbler to the depositor was established with four temperature zones at 65° C., 75° C., 80° C., and 95° C., respectively.

Both stainless-steel bubblers have a flow-through design. The flux of vapor supplied by the bubbler can be controlled by the precursor vapor pressure, which is dictated by the bubbler temperature, and the nitrogen carrier gas flow rate through the bubbler. This flow, called the bubbler flow, is directed through the liquid precursor inside the bubbler. The gas mixture that exits the bubbler is composed of the precursor vapor and nitrogen gas, and is merged with another nitrogen carrier gas flow outside the bubbler. This secondary carrier gas, called the driving flow, enables the user to decouple the precursor flux (defined by the bubbler flow) from the total flow rate (defined by the sum of bubbler and driving flows). Both the bubbler and driving flows for each precursor bubbler are controlled by their own respective mass flow controllers (MFCs), totaling four. A detailed schematic of the bubbler and driving flow configuration is provided in Section 5.1 The bubbler flow rates were 45 and 200 standard cubic centimeters per minute (sccm) and the driving flow rates were 2,200 and 1,000 sccm for the TTIP and H₂O bubblers, respectively.

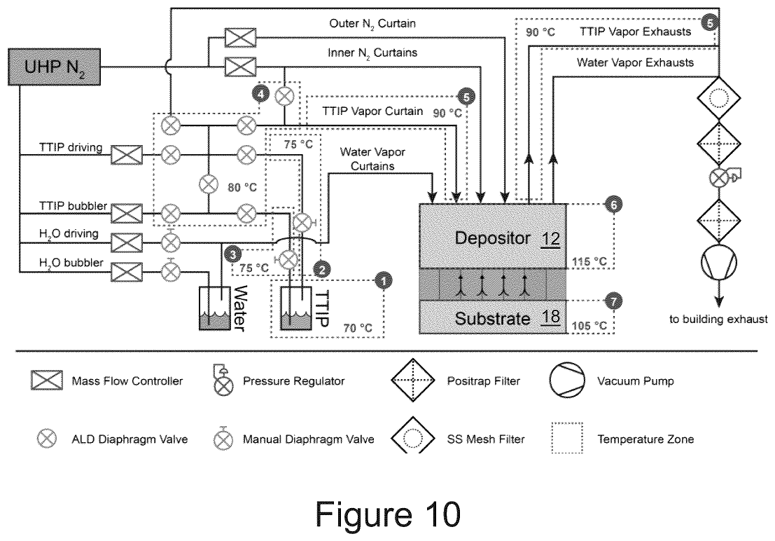

The flow for each of the two inner nitrogen zones was supplied by a combined flow of 10,000 sccm. The outer nitrogen zone surrounded the entire process region on the four equal sides (see FIG. 3). The combined flow for the entire outer nitrogen flow was 25,000 sccm. The exhaust pressure was held at −1.07 kPa, gauge pressure. For all experiments, the gap size was held at 1,000 μm and three-plane alignment was performed unless marked otherwise. Further discussion on the temperature zones, bubblers, and flow components is provided in Section 5.1, along with a full schematic of the fluid control system in FIG. 10.

The flow parameters were selected using a combination of experimentation and calculations. Given the linear velocity of 20 mm s⁻¹, the needed flux of precursor molecules (and therefore bubbler flow rate) was calculated based on the estimated precursor zone width, surface site density, and precursor vapor pressure (see Section 5.7). This established a minimum flow rate for each bubbler flow. By experimentally varying the bubbler flow rate within the rated range of the MFC, the required flow rate needed to achieve saturated, self-limiting films was determined (see FIG. 7 panel b). The driving, inner, and outer nitrogen flow rates were empirically determined with the goal of balancing the pressure distribution within the process region to ensure adequate separation of the precursor zones while also preventing air infiltration from the surrounding ambient.

Film Thickness Measurements: The thickness measurements of the TiO₂ films were performed with two techniques—ellipsometry and spectroscopic reflectometry. Ellipsometry was performed using a Film Sense FS-1 Multi-Wavelength Ellipsometer system with a 65 degrees angle of incidence, a beam size of 4 mm×9 mm, and a Cauchy model. Spectroscopic reflectometry was performed using a Nanospec 6100 system with a 25 μm diameter spot size and a film stack for calculation and fitting of Air-TiO₂—Si. The wavelength dependence of the optical constants (n and k) for the deposited TiO₂ were measured using a Woollam M-2000 Ellipsometer.

XPS Measurements: Measurements were performed using a Kratos Axis Ultra XPS with a monochromated Al KaX-ray source (10 mA, 12 kV). The spot size was 700 μm×300 μm. An electron gun was used to maintain charge neutrality on the surface of each sample. Survey scans (pass energy: 160 eV) were used to quantify the atomic composition of the various samples. Core scans (pass energy: 40 eV) were used to investigate the binding environment of elements in each sample. The binding energies were calibrated to that of adventitious surface carbon (284.8 eV) [Ref. 56]. Argon sputtering was performed for three minutes, which corresponds to a film thickness reduction of ˜3 nm, to remove adventitious carbon on the surface. CasaXPS software was used to analyze the XPS data.

### 5.1 Fluid Control System

Since SALD is a chemical vapor deposition (CVD) based process, control over the flow rates and pressures is critical. The fluid control system designed is shown in FIG. 10. All gas flows are fed by liquid dewar of ultra-high-purity (UHP) nitrogen (99.999%, N₂, Cryogenic Gases). The metal and water precursor vapor zones are generated using stainless-steel, liquid precursor bubblers. The flow through the bubbler, called the bubbler flow, helps form precursor vapor. The mixed nitrogen and precursor vapor flow is met with another nitrogen flow, called the driving flow, which drives the generated vapors through the flow components and depositor head. Both the bubbler and driving flows for each precursor bubbler are controlled by their own respective mass flow controllers (MFCs), totaling four. To avoid cross-contamination, inner nitrogen zones create higher-pressure barriers between the precursor zones to encourage each into their respective exhaust lines and to aid removing adsorbed molecules on the surface. A single MFC controls the combined inner nitrogen curtain flow into the depositor head which then creates the two distinct zones. A single MFC controls the outer nitrogen flow.

A valve system was developed with six two-way ultra-high purity (UHP) ALD diaphragm sealed valves, one three-way UHP ALD diaphragm sealed valve, and two manual ball valves. The valve arrangement was designed for cycled pumping and nitrogen purging of the metal vapor lines. The depositor head manifold channels and hoses leading to it cannot be evacuated as the depositor head is open to the atmosphere and unable to be sealed. Thus prior to a deposition process, this remaining volume is flushed with nitrogen to purge any remaining contaminants. These steps along with baking the system at elevated temperatures (discussed below) help reduce the water vapor and oxygen within the system.

The diaphragm valves are actuated pneumatically, and each has a matching solenoid valve that controls the compressed air supply to open or close the valve. The manual ball valves are connected directly to the metal precursor bubbler to ensure purity of the bubbler. All the flow components that are directly exposed to metal precursors are stainless steel and fitted with metal, face-sealing gaskets. Any tubing not designed for direct exposure, but that potentially could be exposed to trace amounts, is polytetrafluoroethylene (PTFE) fitted with stainless-steel compression connections.

Once the metal vapors are generated, condensation must be avoided within the system to prevent clogging of the flow components and to ensure the precursor reaches the substrate surface. An increasing temperature gradient is established across the flow components from the metal bubbler to the valves, hoses, and tubing to the depositor head and substrate. The water bubbler and all water specific tubing are held at room temperature.

The first temperature zone is the metal precursor bubbler which is immersed in a circulating bath with the ability to heat or cool, enabling a wide range of bubbler temperatures depending on the specific characteristics of the precursor. The next four temperature zones cover the series of valves, hoses, and tubing that the metal vapor flows through as it moves towards the depositor head. The depositor head is heated by the sixth zone. Polyimide patch heaters (Watlow, Inc.) were custom designed to fit around the welded tube fittings to provide uniform heating to the depositor. The seventh zone heats the substrate plate with a polyimide patch heater on the bottom of the plate. For each zone, layers of aluminum foil were wrapped around components and heaters to assist in uniform heating which were then wrapped in fiberglass encased in foil to insulate the system. To monitor and control the heating zone temperatures, multiple thermocouples are placed throughout the system.

The exhaust lines have a pressure slightly lower than atmosphere (approx. −1 kPa, gauge) to draw the unreacted precursor and reaction byproducts into the building exhaust, keeping the precursors in their respective zones. The four exhaust zones are connected to a single pressure regulator and a vacuum pump. The two inner exhaust zones are designed to carry the excess metal vapor and reaction products, while the outer two exhaust zones are designed for that of water vapor. The two exhaust types meet in a three-way stainless steel mesh trap where the excess precursor flows begin to mix and react. This mixed flow then proceeds through an activated charcoal filter to further remove any unreacted metal precursor from the exhaust flow. A molecular sieve filter is placed on the vacuum pump inlet to reduce water vapor from entering the pump system. 5.2 Depositor Manifold

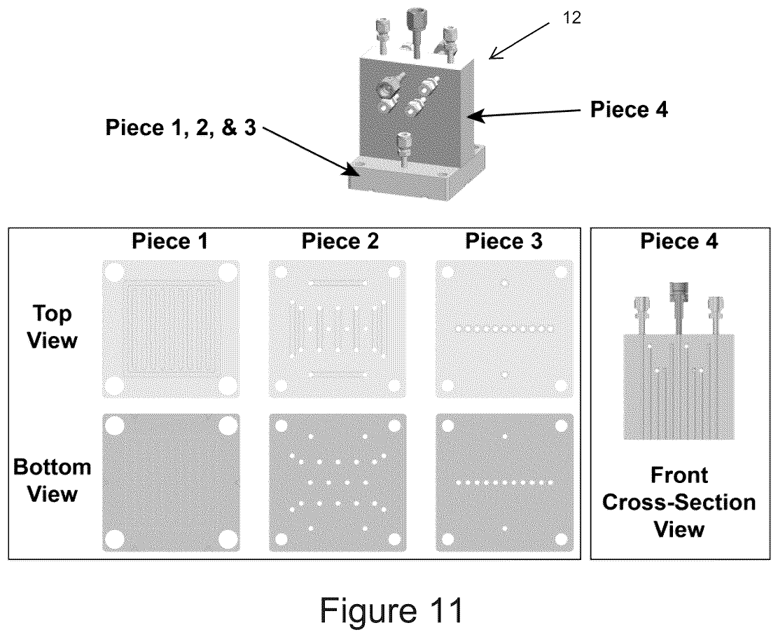

The depositor manifold creates the precursor and nitrogen curtains. The input gases are directed through the depositor manifold which has internal flow channels to distribute the gases to their respective zones. The depositor is formed by four distinct plates which are furnace brazed together, shown in FIG. 11. VCR and compression gas fittings are welded to the assembly for the hose connections. The flow channels terminate in small pinholes (diameter=1.016 mm) on the bottom surface of the depositor.

### 5.3 Plane and Alignment Calculations

To solve for the plane equation of the substrate plane (P2), the three-axis coordinates can be plugged into a system of three equations shown in Equation ES1, Equation ES2, and Equation ES3, where the numeric subscripts reference a specific capacitance probe sensor. The x- and y-coordinates are fixed by the mounting location of each sensor relative to the origin, which is defined as the center of the depositor. The z-values are determined by the capacitance probe sensor measurements, which assumes the depositor surface to be zero. In Equation ES4, D is established as the matrix of the three-axis probe coordinates. The values of a, b, and c are calculated using Equation ES5, Equation ES6, and Equation ES7, where d is the desired gap distance. With a, b, and c calculated, the equation for the plane is set. The needed change in gap size to achieve parallel alignment, Δz, for each stepper motor can be calculated using Equation ES8, Equation ES9, and Equation ES10. These needed gap size changes are then communicated to the linear actuators (L1, L2, and L3) which then move the system into parallel alignment.

$$a * {x}_{1} + b * {y}_{1} + c * {z}_{1} + d = 0 \qquad ( ES 1 )$$

$$a * {x}_{2} + b * {y}_{2} + c * {z}_{2} + d = 0 \qquad ( ES 2 )$$

$$a * {x}_{3} + b * {y}_{3} + c * {z}_{3} + d = 0 \qquad ( ES 3 )$$

$$D = [ \begin{matrix}{x}_{1} & {y}_{1} & {z}_{1} \\ {x}_{2} & {y}_{2} & {z}_{2} \\ {x}_{3} & {y}_{3} & {z}_{3}\end{matrix} ] \qquad ( ES 4 )$$

$$a = \frac{- d}{D} [ \begin{matrix}1 & {y}_{1} & {z}_{1} \\ 1 & {y}_{2} & {z}_{2} \\ 1 & {y}_{3} & {z}_{3}\end{matrix} ] \qquad ( ES 5 )$$

$$b = \frac{- d}{D} [ \begin{matrix}{x}_{1} & 1 & {z}_{1} \\ {x}_{2} & 1 & {z}_{2} \\ {x}_{3} & 1 & {z}_{3}\end{matrix} ] \qquad ( ES 6 )$$

$$c = \frac{- d}{D} [ \begin{matrix}{x}_{1} & {y}_{1} & 1 \\ {x}_{2} & {y}_{2} & 1 \\ {x}_{3} & {y}_{3} & 1\end{matrix} ] \qquad ( ES 7 )$$

$$Δ {z}_{1} = d + \frac{d + a * {x}_{1} + b * {y}_{1}}{c} \qquad ( ES 8 )$$

$$Δ {z}_{2} = d + \frac{d + a * {x}_{2} + b * {y}_{2}}{c} \qquad ( ES 9 )$$

$$Δ {z}_{3} = d + \frac{d + a * {x}_{3} + b * {y}_{3}}{c} \qquad ( ES 10 )$$

### 5.4 Effect of X-Axis Travel Range on Deposition Geometry

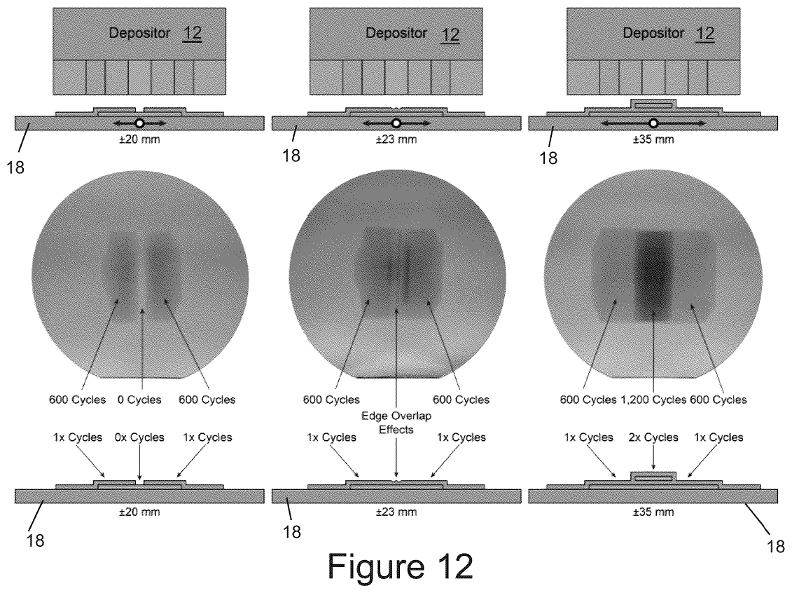

The depositor creates one metal precursor zone (TTIP, orange) and two oxidant zones (water, blue) and x-axis motion exposes the substrate to the alternating precursors. The further that the substrate is moved in a reciprocating motion, the larger the deposited area of TiO₂ will be. However, moving further does not just give a larger film with the same thickness. If the substrate is moved far enough, the surface will be exposed to two cycles of the precursor for a single mechanical cycle. For the described depositor design, the transition between single layer and double layer patterning occurs at ±23 mm as shown in FIG. 12. If the substrate is moved less than ±23 mm, two disjointed region of single layer patterning are deposited. If the substrate is moved more than ±23 mm, one continuous film is formed with a region twice as thick as the sides in the center. Printing with exactly ±23 mm results in a deposited film the largest single layer regions without any double patterning in the middle. However, the middle region does display some non-uniformity due to edge overlap effects.

### 5.5 Bulk TiO₂ Films

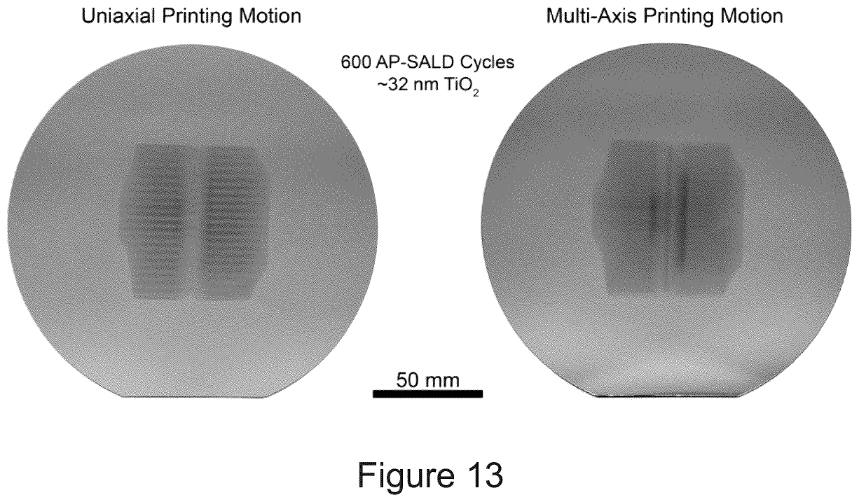

Multi-axis printing is demonstrated to deposit more uniform TiO₂ films. Uniaxial printing in only the x-axis deposits a bulk TiO₂ film shape and color as seen in FIG. 13. The multi-axis printing approach with both x-axis and y-axis motion results in a more uniform film in the single patterned sections on the left and right, reducing the lateral striations. However, the middle region of the multi-axis printing sample does appear to be more pronounced. The darker vertical lines are a result of the edge overlap effects as discussed in Section 5.4, Effect of X-Axis Travel Range on Deposition Geometry. The precursor zones are formed by gas curtains and as such do not have sharp, crisp edges. When traveling ±23 mm, the precursor zones are swept the theoretical distance to achieve the largest area of single deposition, while avoiding double deposition. However, the fuzzy edge to the precursor zones can cause some double deposition at the inner edges of the swept H₂O zones. With the added step in the y-axis, the multi-axis printing process adds to the residence time at this boundary thus depositing a thicker and darker film. One can observe the same features of the multi-axis printing sample in the uniaxial case, albeit fainter and separated into dots.

### 5.6 Capacitance Probe Sensor Calibration

Each capacitance probe sensor outputs a measured voltage, which is then converted to a distance. To calibrate the distance measurement, the substrate was brought into contact with the depositor surface to zero the signal and then moved away from the depositor in 100 μm increments by the known step size of the linear actuators (L1, L2, and L3 in FIG. 2 panel b) over the full measurement range. At each location, the measured voltage for each sensor was recorded. In accordance with the manufacturer's instructions, a 5^{th}-order polynomial was fitted to the data for each capacitance probe sensor, resulting in a voltage-to-distance calibration.

### 5.7 Molar Flux Calculations

Values and equations to solve for the minimum bubbler flow rates for both TTIP and H₂O are in Table 1. This assumes a utilization of 10% of the precursor that is delivered to the process region.

TABLE 1
Values for molar flux calculations

| Variable | Description | Value | Units | Ref. |
|---|---|---|---|---|
| v | Velocity of substrate | 20 | mm s⁻¹ | Experimental |
| w | Width of precursor curtain | 65 | mm | Experimental |
| A | Areal throughput | 0.0013 | m² s⁻¹ | ES11 |
| Γ_{H}_{₂}_{O} | Surface site density for H₂O | 2.4908e−5 | mol m⁻² | [1] |
| Γ_{TTIP} | Surface site density for TTIP | 2.4909e−6 | mol m⁻² | [1] |
| R | Molar gas constant | 8.314 | J mol⁻¹ K⁻¹ | Constant |
| T_{std} | Standard temperature | 273.15 | K | Constant |
| P_{std} | Standard pressure | 1 | atm | Constant |
| P_{bub} | Bubbler pressure | 1 | atm | Assumption |
| T_{H}_{₂}_{O-bub} | Bubbler temperature for H₂O | 25 | C. | Experiment |
| T_{TTIP-bub} | Bubbler temperature for TTIP | 343.15 | K | Experiment |
| P_{TTIP-vap} | Vapor pressure of TTIP | 158.64 | Pa | ES12 |
| P_{H}_{₂}_{O-vap} | Vapor pressure of H₂O | 3168.5 | Pa | ES13 [3] |
| f | Utilization factor | 0.1 | [symbol] | Assumption |
| Q_{TTIP-bub} | Minimum bubbler flow rate for TTIP | 27.8 | sccm | ES14 [4] |
| Q_{H}_{₂}_{O-bub} | Minimum bubbler flow rate for H₂O* | 27.9 | sccm | ES14 [4] |

*this value is doubled as there are two water curtains within the process region
[1] M. Reinke, Y. Kuzminykh, and P. Hoffmann, Journal of Physical Chemistry C 2015, 110, 50, 27965-27971
[2] F. D. Duminica, F. Maury, and F. Senocq, Surface and Coatings Technology, 2004, 188-189, 255-259, 0257-8972
[3] A. L. Buck, The Journal of Applied Meteorology and Climatology 1981, 1527-1532
[4] K. Seshan, Handbook of Thin-Film Deposition Processes and Techniques. 2nd Ed., 2002 [symbol]
indicates data missing or illegible when filed

$$\dot{A} = v * w \qquad ( ES 11 )$$

$${P}_{TTIP - vap} = {10}^{9.465 - \frac{3222}{{T}_{TTIP - bub}}} \qquad ( ES 12 )$$

$${P}_{{H}_{2} O - vap} = {e}^{( 18.678 - \frac{{T}_{{H}_{2} O - bub}}{234.5} ) ( \frac{{T}_{{H}_{2} O - bub}}{257.4 + {T}_{{H}_{2} O - bub}} )} \qquad ( ES 13 )$$

$${Q}_{i - bub} = \frac{\dot{A} * {Γ}_{i}}{f \frac{{P}_{i - vap}}{{P}_{imb}} \frac{{P}_{std}}{R * {T}_{std}}} \qquad ( ES 14 )$$

### 5.8 Film Comparison Varying Velocity

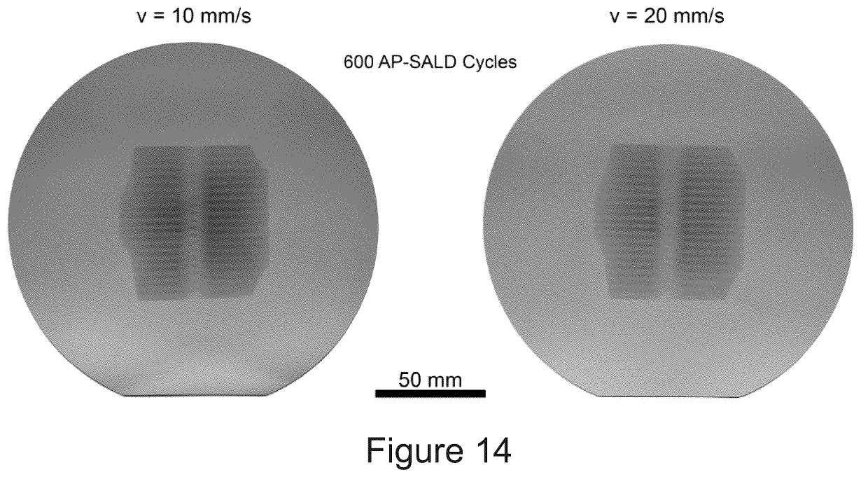

TiO₂ films are deposited with a substrate velocity of 20 mm s⁻¹ (right panel of FIG. 14). Periodic variations in the film thickness can clearly be observed as lines along the x-axis. To study the influence of substrate velocity on these film non-uniformities, SALD was performed with a substrate velocity of 10 mm s⁻¹ (left panel of FIG. 14). Visually, the periodic variations in film thickness are still observed in the 10 mm s⁻¹ case and the deviation from the average thickness was measured/calculated as ±9.05%. For the 20 mm s⁻¹ sample, the deviation from the average thickness was measured/calculated as ±8.22%. The film uniformity was not improved, and the total process time was doubled. Both outcomes are undesirable. While one might be able to reduce the substrate velocity enough to achieve a sufficiently uniform film, the throughput of the system would suffer greatly. The proposed solution of multi-axis printing described in Section 3.2 improves uniformity while not being limited by substrate velocity, which has a significant impact on process throughput. The reported method only increases the total process time by −3.5% while reducing variation by nearly a factor of four.

### REFERENCES

[1] S. M. George, Chem. Rev. 2010, 110, 111.
[2] R. W. Johnson, A. Hultqvist, S. F. Bent, Mater. Today 2014, 17, 236.
[3] M. Ritala, J. Niinistö, ECS Trans. 2009, 25, 641.
[4] T. Suntola, J. Antson, (Individual), U.S. Pat. No. 4,058,430A, 1977.
[5] T. S. Suntola, A. J. Pakkala, S. G. Lindfors, (Lohja Oy AB), U.S. Pat. No. 4,389,973A, 1983.
[6] P. Poodt, D. C. Cameron, E. Dickey, S. M. George, V. Kuznetsov, G. N. Parsons, F. Roozeboom, G. Sundaram, A. Vermeer, J. Vac. Sci. Technol., A 2011, 30, 010802.
[7] R. L. Z. Hoye, D. Muñoz-Rojas, S. F. Nelson, A. Illiberi, P. Poodt, F. Roozeboom, J. L. MacManus-Driscoll, APL Mater. 2015, 3, 040701.
[8] P. Poodt, A. Lankhorst, F. Roozeboom, K. Spee, D. Maas, A. Vermeer, Adv. Mater. 2010, 22, 3564.
[9] A. Illiberi, R. Scherpenborg, F. Roozeboom, P. Poodt, ECS J. Solid State Sci. Technol. 2014, 3, P111.
[10] A. S. Yersak, Y. C. Lee, J. A. Spencer, M. D. Groner, J. Vac. Sci. Technol., A 2013, 32, 01A130.
[11] E. Dickey, W. A. Barrow, J. Vac. Sci. Technol., A 2012, 30, 021502.
[12] S. Suh, S. Park, H. Lim, Y.-J. Choi, C. Seong Hwang, H. Joon Kim, S.-J. Won, J. Vac. Sci. Technol., A 2012, 30, 051504.
[13] A. Illiberi, I. Katsouras, S. Gazibegovic, B. Cobb, E. Nekovic, W. van Boekel, C. Frijters, J. Maas, F. Roozeboom, Y. Creyghton, P. Poodt, G. Gelinck, J. Vac. Sci. Technol., A 2018, 36, 04F401.
[14] P. S. Maydannik, T. O. Kääriäinen, D. C. Cameron, Chem. Eng. J. 2011, 171, 345.
[15] K. Sharma, R. A. Hall, S. M. George, J. Vac. Sci. Technol., A 2014, 33, 01A132.
[16] D. H. Levy, D. Freeman, S. F. Nelson, P. J. Cowdery-Corvan, L. M. Irving, Appl. Phys. Lett. 2008, 92, 192101.
[17] D. H. Levy, S. F. Nelson, D. Freeman, J. Disp. Technol. 2009, 5, 484.
[18] M. B. M. Mousa, J. S. Ovental, A. H. Brozena, C. J. Oldham, G. N. Parsons, J. Vac. Sci. Technol., A 2018, 36, 031517.
[19] H. Choi, S. Shin, H. Jeon, Y. Choi, J. Kim, S. Kim, S. C. Chung, K. Oh, J. Vac. Sci. Technol., A 2015, 34, 01A121.
[20] D. Muñoz-Rojas, H. Sun, D. C. Iza, J. Weickert, L. Chen, H. Wang, L. Schmidt-Mende, J. L. MacManus-Driscoll, Prog. Photovolt.: Res. Appl. 2013, 21, 393.
[21] A. Sekkat, V. H. Nguyen, C. A. Masse de La Huerta, L. Rapenne, D. Bellet, A. Kaminski-Cachopo, G. Chichignoud, D. Muñoz-Rojas, Commun. Mater. 2021, 2, 1.
[22] M.-J. Zhao, Z.-T. Sun, C.-H. Hsu, P.-H. Huang, X.-Y. Zhang, W.-Y. Wu, P. Gao, Y. Qiu, S.-Y. Lien, W.-Z. Zhu, Nanomaterials 2020, 10, 459.
[23] C.-H. Hsu, R.-F. Zhu, P.-C. Kang, P. Gao, W.-Y. Wu, D.-S. Wuu, S.-Y. Lien, W.-Z. Zhu, Mater. Lett. 2023, 340, 134204.
[24] G. Gurbandurdyyev, K. Mistry, L.-V. Delumeau, J. Y. Loke, C. H. Teoh, J. Cheon, F. Ye, K. C. Tam, K. P. Musselman, ChemNanoMat 2023, 9, 202200498.
[25] P. R. Fitzpatrick, Z. M. Gibbs, S. M. George, J. Vac. Sci. Technol., A 2011, 30, 01A136.
[26] Z. Deng, W. He, C. Duan, R. Chen, B. Shan, J. Vac. Sci. Technol., A 2015, 34, 01A108.
[27] C. A. M. de la Huerta, V. H. Nguyen, A. Sekkat, C. Crivello, F. Toldra-Reig, P. B. Veiga, S. Quessada, C. Jimenez, D. Muñoz-Rojas, Adv. Mater. Technol. 2020, 5, 2000657.
[28] L. Midani, W. Ben-Yahia, V. Salles, C. Marichy, ACS Appl. NanoMater. 2021, 4, 11980.
[29] V. H. Nguyen, J. Resende, C. Jiménez, J.-L. Deschanvres, P. Carroy, D. Muñoz, D. Bellet, D. Muñoz-Rojas, J. Renewable Sustainable Energy 2017, 9, 021203.
[30] C. Armstrong, L.-V. Delumeau, D. Muñoz-Rojas, A. Kursumovic, J. MacManus-Driscoll, K. P. Musselman, Nanoscale Adv. 2021, 3, 5908.
[31] B. Díaz, E. Härkönen, J. Światowska, V. Maurice, A. Seyeux, P. Marcus, M. Ritala, Corros. Sci. 2011, 53, 2168.
[32] J. Wang, S. Lee, A. R. Bielinski, K. A. Meyer, A. Dhyani, A. M. Ortiz-Ortiz, A. Tuteja, N. P. Dasgupta, Adv. Mater. Interfaces 2020, 7, 2000672.
[33] A. Khan, V. H. Nguyen, D. Muñoz-Rojas, S. Aghazadehchors, C. Jiménez, N. D. Nguyen, D. Bellet, ACS Appl. Mater. Interfaces 2018, 10, 19208.
[34] L. Bardet, M. Akbari, C. Crivello, L. Rapenne, M. Weber, V. H. Nguyen, C. Jimenez, D. Muñoz-Rojas, A. Denneulin, D. Bellet, ACS Appl. Nano Mater. 2023, 6, 15234.
[35] H. Myja, Z. Yang, I. A. Goldthorpe, A. J. B. Jones, K. P. Musselman, A. Grundmann, H. Kalisch, A. Vescan, M. Heuken, T. Kümmell, G. Bacher, Nanotechnol. 2023, 34, 285201.
[36] F. Toldra-Reig, C. Lausecker, M. Weber, M. Bechelany, D. Muñoz-Rojas, ACS Sustainable Chem. Eng. 2022, 10, 14112.
[37] M. B. M. Mousa, C. J. Oldham, G. N. Parsons, ACS Appl. Mater. Interfaces 2015, 7, 19523.
[38] Z. Li, K. Cao, X. Li, R. Chen, Int. J. Heat Mass Transfer 2021, 181, 121854.
[39] D. Pan, T.-C. Jen, C. Yuan, Int. J. Heat Mass Transfer 2016, 96, 189.
[40] C. Masse de la Huerta, V. H. Nguyen, J.-M. Dedulle, D. Bellet, C. Jiménez, D. Muñoz-Rojas, Coatings 2019, 9, 5.
[41] D. Pan, Chem. Eng. Sci. 2021, 234, 116447.
[42] Z. Li, X. Li, K. Cao, R. Chen, ECS Trans. 2020, 98, 137.
[43] V. H. Nguyen, A. Sekkat, C. Jiménez, D. Muñoz, D. Bellet, D. Muñoz-Rojas, Chem. Eng. J. 2021, 403, 126234.
[44] C.-H. Hsu, K.-T. Chen, P.-H. Huang, W.-Y. Wu, X.-Y. Zhang, C. Wang, L.-S. Liang, P. Gao, Y. Qiu, S.-Y. Lien, Z.-B. Su, Z.-R. Chen, W.-Z. Zhu, Nanomater. 2020, 10, 1322.
[45] E. Zimmermann, K. K. Wong, T. Seewald, J. Kalb, J. Linke, G. Hahn, L. Schmidt-Mende, Int. J. Photoenergy 2022, 2022, el172871.
[46] C.-T. Hsieh, C.-H. Chao, W.-J. Ke, Y.-F. Lin, H.-W. Liu, Y. A. Gandomi, S. Gu, C.-Y. Su, J.-K. Chang, J. Li, C.-C. Fu, B. Chandra Mallick, R.-S. Juang, ACS Appl. Energy Mater. 2020, 3, 10619.
[47] C.-T. Hsieh, B. C. Mallick, Y. A. Gandomi, Y.-C. Huang, C.-C. Fu, R.-S. Juang, J.-K. Chang, Electrochim. Acta 2022, 423, 140605.
[48] M. Aghaee, P. S. Maydannik, P. Johansson, J. Kuusipalo, M. Creatore, T. Homola, D. C. Cameron, J. Vac. Sci. Technol., A 2015, 33, 041512.
[49] M. Ritala, M. Leskela, L. Niinisto, P. Haussalo, Chem. Mater. 1993, 5, 1174.
[50] M. Reinke, Y. Kuzminykh, P. Hoffmann, J. Phys. Chem. C 2016, 120, 4337.
[51] S. E. Potts, W. M. M. Kessels, Coord. Chem. Rev. 2013, 257, 3254.
[52] Q. Xie, J. Musschoot, D. Deduytsche, R. L. V. Meirhaeghe, C. Detavernier, S. V. d. Berghe, Y.-L. Jiang, G.-P. Ru, B.-Z. Li, X.-P. Qu, J. Electrochem. Soc. 2008, 155, H688.
[53] Q. Xie, Y.-L. Jiang, C. Detavernier, D. Deduytsche, R. L. Van Meirhaeghe, G.-P. Ru, B.-Z. Li, X.-P. Qu, J. Appl. Phys. 2007, 102, 083521.
[54] P. R. McCurdy, L. J. Sturgess, S. Kohli, E. R. Fisher, Appl. Surf. Sci. 2004, 233, 69.
[55] A. Sonnenfeld, P. R. von Sonnenfeld, R. Hauert, Plasma Chem. Plasma Process. 2006, 26, 319.
[56] Z. J. Berquist, A. J. Gayle, N. P. Dasgupta, A. Lenert, Adv. Funct. Mater. 2022, 32, 2108774.

The citation of any document or reference is not to be construed as an admission that it is prior art with respect to the present invention.

Thus, the present invention provides an atmospheric-pressure spatial atomic layer deposition system that reduces the non-uniformity of the film produced by the atomic layer deposition system.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as “in one embodiment”, “in another embodiment”, “in certain embodiments”, or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein. Various features and advantages of the invention are set forth in the following claims.

What is claimed is:

1. An atomic layer deposition system comprising:
a depositor head having an active surface configured to discharge a flow of a first precursor gas, a flow of a second precursor gas, and a flow of an inert gas that separates the flow of the first precursor gas and the flow of the second precursor gas;
a substrate spaced apart from the active surface of the depositor head;
an XY motion device operably coupled to the substrate or the depositor head; and
a controller in electrical communication with the XY motion device, the controller being configured to execute a program stored in the controller to move the XY motion device such that the substrate or the depositor head moves in a path, wherein a position of the substrate relative to the depositor head varies in both an X direction and a Y direction when the substrate or the depositor head follows the path.

2. The atomic layer deposition system of claim 1 wherein:
the path is selected to produce a film having a uniform thickness over a region of the film on the substrate.

3. The atomic layer deposition system of claim 1 wherein:
the system further comprises a first precursor gas source for containing the first precursor gas, a second precursor gas source for containing the second precursor gas, and a third source for containing the inert gas, and
the active surface of the depositor head includes a plurality of first passageways in fluid communication with the first precursor gas source via a first precursor gas conduit, a plurality of second passageways in fluid communication with the second precursor gas source via a second precursor gas conduit, and a plurality of third passageways in fluid communication with the third source via a gas conduit,
the system further comprises a valve apparatus comprising: (i) a first valve in the first precursor gas conduit, (ii) a second valve in the second precursor gas conduit, and (iii) a third valve in the gas conduit, and
the controller is in electrical communication with the valve apparatus, the controller being configured to execute the program stored in the controller to move the first valve, the second valve, and the third valve into an open position to deliver the first precursor gas to a first reaction zone between the active surface of the depositor head and the substrate, to deliver the second precursor gas to a second reaction zone between the active surface of the depositor head and the substrate, and to deliver the inert gas to a gas barrier zone between the active surface of the depositor head and the substrate.

4. The atomic layer deposition system of claim 3 wherein:
the first passageways, the second passageways, and the third passageways are arranged in linear rows.

5. The atomic layer deposition system of claim 1 wherein:
the active surface of the depositor head further comprises a plurality of exhaust passageways, each of the plurality of exhaust passageways being in fluid communication with one of a plurality of exhaust zones between the active surface of the depositor head and the substrate.

6. The atomic layer deposition system of claim 1 wherein:
the substrate is positioned on a substrate plate connected to the XY motion device.

7. The atomic layer deposition system of claim 6 wherein:
the controller executes the program stored in the controller to move the XY motion device such that the substrate plate moves in the path wherein the position of the substrate plate relative to the depositor head varies in both the X direction and the Y direction when the substrate plate follows the path.

8. The atomic layer deposition system of claim 1 wherein:
the XY motion device is connected to the depositor head.

9. The atomic layer deposition system of claim 1 wherein:
the path has a shape selected from the group consisting of closed shapes having a plurality of line segments, open shapes having a plurality of line segments, and wave shaped.

10. The atomic layer deposition system of claim 1 wherein:
the path has a rectangular shape.

11. The atomic layer deposition system of claim 1 wherein:
the depositor head is mounted to a robotic arm.

12. A method for atomic layer deposition, the method comprising:
(a) providing an atomic layer deposition system comprising a depositor head and a substrate;
(b) supplying a first precursor gas, a second precursor gas, and an inert gas to the depositor head; and
(c) moving the substrate or the depositor head in a path selected to produce a film having a uniform thickness on the substrate wherein a position of the substrate relative to the depositor head varies in both an X direction and a Y direction when the substrate or the depositor head follows the path.

13. The method of claim 12 wherein:
the atomic layer deposition system comprises an XY motion device operably coupled to the substrate or the depositor head, and
the XY motion device moves such that the position of the substrate relative to the depositor head varies in both the X direction and the Y direction when the substrate or the depositor head follows the path.

14. The method of claim 12 wherein:
the atomic layer deposition system comprises an XY motion device operably coupled to the substrate, and
the XY motion device moves such that the position of the substrate relative to the depositor head varies in both the X direction and the Y direction when the substrate follows the path.

15. The method of claim 12 wherein:
the substrate is positioned on a substrate plate connected to the XY motion device.

16. The method of claim 12 wherein:
the atomic layer deposition system comprises an XY motion device operably coupled to the depositor head, and
the XY motion device moves such that the position of the substrate relative to the depositor head varies in both the X direction and the Y direction when the depositor head follows the path.

17. The method of claim 12 wherein:
the path has a shape selected from the group consisting of closed shapes having a plurality of line segments, open shapes having a plurality of line segments, and wave shaped.

18. The method of claim 12 wherein:
the path has a rectangular shape.

19. The method of claim 12 wherein:
step (c) comprises moving the substrate or the depositor head in the path selected to produce a film having a non-uniformity of less than ±30%.

20. The method of claim 12 wherein:
step (c) comprises moving the substrate or the depositor head in the path selected to produce a film having a non-uniformity of less than ±20%.

21. The method of claim 12 wherein:
step (c) comprises moving the substrate or the depositor head in the path selected to produce a film having a non-uniformity of less than ±10%.

22. The method of claim 12 wherein:
step (c) comprises moving the substrate or the depositor head in the path selected to produce a film having a non-uniformity of less than ±5%.

23. A method for reducing non-uniformity of a film produced by atomic layer deposition, the method comprising:
(a) providing an atomic layer deposition system comprising a depositor head and a substrate;
(b) supplying a first precursor gas, a second precursor gas, and an inert gas to the depositor head; and
(c) moving the substrate or the depositor head in a path selected to produce a film having a uniform thickness on the substrate wherein a position of the substrate relative to the depositor head varies in both an X direction and a Y direction when the substrate or the depositor head follows the path.

24. The method of claim 23 wherein:
the atomic layer deposition system comprises an XY motion device operably coupled to the substrate or the depositor head, and
the XY motion device moves such that the position of the substrate relative to the depositor head varies in both the X direction and the Y direction when the substrate or the depositor head follows the path.

25. The method of claim 23 wherein:
the atomic layer deposition system comprises an XY motion device operably coupled to the substrate, and
the XY motion device moves such that the position of the substrate relative to the depositor head varies in both the X direction and the Y direction when the substrate follows the path.

26. The method of claim 25 wherein:
the substrate is positioned on a substrate plate connected to the XY motion device.

27. The method of claim 23 wherein:
the atomic layer deposition system comprises an XY motion device operably coupled to the depositor head, and
the XY motion device moves such that the position of the substrate relative to the depositor head varies in both the X direction and the Y direction when the depositor head follows the path.

28. The method of claim 23 wherein:
the path has a shape selected from the group consisting of closed shapes having a plurality of line segments, open shapes having a plurality of line segments, and wave shaped.

29. The method of claim 23 wherein:
the path has a rectangular shape.

30. The method of claim 23 wherein:
step (c) comprises moving the substrate or the depositor head in the path selected to produce a film having a non-uniformity of less than ±30%.

31. The method of claim 23 wherein:
step (c) comprises moving the substrate or the depositor head in the path selected to produce a film having a non-uniformity of less than ±20%.

32. The method of claim 23 wherein:
step (c) comprises moving the substrate or the depositor head in the path selected to produce a film having a non-uniformity of less than ±10%.

33. The method of claim 23 wherein:
step (c) comprises moving the substrate or the depositor head in the path selected to produce a film having a non-uniformity of less than ±5%.
